(19) United States
(12) Patent Application Publication
(10) Pub. No.: US 2024/0074251 A1
(43) Pub. Date: Feb. 29, 2024

(54) DISPLAY APPARATUS AND METHOD OF MANUFACTURING THE SAME

(71) Applicant: Samsung Display Co., Ltd., Yongin-si (KR)

(72) Inventors: Donghyun Son, Yongin-si (KR); Sola Lee, Yongin-si (KR); Kiyoung Kim, Yongin-si (KR); Jongseok Kim, Yongin-si (KR)

(73) Assignee: Samsung Display Co., Ltd., Yongin-si (KR)

(21) Appl. No.: 18/454,505

(22) Filed: Aug. 23, 2023

(30) Foreign Application Priority Data
Aug. 24, 2022 (KR) 10-2022-0106353

(51) Int. Cl. H10K 59/124; H10K 59/12

(52) U.S. Cl. CPC H10K 59/124; H10K 59/1201

(57) ABSTRACT

A display apparatus includes a substrate including a component area including a transmission area, a main area outside the component area, and a bending area bent based on a bending axis, a buffer layer disposed on the substrate, a first semiconductor layer disposed on the buffer layer, and a first gate insulating layer overlapping the first semiconductor layer and including a 1-1^{st} opening corresponding to the bending area, and a 1-1^{st} through-hole exposing a portion of the first semiconductor layer. A first acute angle formed by an inner surface of the 1-1^{st} opening with respect to an upper surface of the substrate is less than a first contact acute angle formed by an inner surface of the 1-1^{st} through-hole with respect to the upper surface of the substrate.

### CROSS-REFERENCE TO RELATED APPLICATION(S)

This application claims priority to and benefits of Korean Patent Application No. 10-2022-θ106353 under 35 U.S.C. § 119, filed on Aug. 24, 2022 in the Korean Intellectual Property Office, the entire contents of which is incorporated herein by reference.

### BACKGROUND

### 1. Technical Field

One or more embodiments relate to a display apparatus, in which it is possible to prevent or minimize a conductive material remaining around a portion of a bending area from which an inorganic layer is removed, and a method of manufacturing the display apparatus.

### 2. Description of the Related Art

A display apparatus displays an image by receiving information about the image. The display apparatus may include a bending area, and the bending area may receive stress occurring due to bending. To prevent various problems, such as cracks occurring in an inorganic layer due to the stress, etc., the inorganic layer may be removed from the bending area.

However, a conductive material unintentionally remaining around a region from which the inorganic layer is removed may cause defects.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus, in which it is possible to prevent or minimize a conductive material remaining around a portion of a bending area from which an inorganic layer is removed, and a method of manufacturing the display apparatus. However, this aspect is an example and does not limit the scope of the disclosure.

Additional aspects will be set forth in part in the description which follows and, in part, will be apparent from the description, or may be learned by practice of the embodiments of the disclosure.

According to one or more embodiments, a display apparatus may include a substrate including a component area including a transmission area, a main area outside the component area, and a bending area bent based on a bending axis, a buffer layer located on the substrate, a first semiconductor layer disposed on the buffer layer, and a first gate insulating layer overlapping the first semiconductor layer and including a 1-1^{st} opening corresponding to the bending area, and a 1-1^{st} through-hole exposing a portion of the first semiconductor layer. A first acute angle formed by an inner surface of the 1-1^{st} opening with respect to an upper surface of the substrate may be less than a first contact acute angle formed by an inner surface of the 1-1^{st} through-hole with respect to the upper surface of the substrate.

The display apparatus may further include a plurality of auxiliary pixels arranged in the component area. The first gate insulating layer may further include a 2-1^{st} opening corresponding to the transmission area disposed between the plurality of auxiliary pixels.

A second acute angle formed by an inner surface of the 2-1^{st} opening with respect to the upper surface of the substrate may be the same as the first acute angle.

The display apparatus may further include a second gate insulating layer disposed on the first gate insulating layer, a second semiconductor layer disposed on the second gate insulating layer, and a third gate insulating layer overlapping the second semiconductor layer.

The second gate insulating layer may include a 1-2^{nd} through-hole corresponding to the 1-1^{st} through-hole. An inner surface of the 1-2^{nd} through-hole and the inner surface of the 1-1^{st} through-hole may form a continuous surface with each other.

The third gate insulating layer may include a 2-1^{st} through-hole exposing a portion of the second semiconductor layer and may include a second contact acute angle formed by an inner surface of the 2-1^{st} through-hole with respect to the upper surface of the substrate.

The buffer layer may include a 3-1^{st} opening corresponding to the bending area. A third acute angle formed by an inner surface of the 3-1^{st} opening with respect to the upper surface of the substrate may be less than the first acute angle.

The third acute angle may be less than the second contact acute angle.

When viewed in a direction perpendicular to the substrate, an area of the 1-1^{st} opening may be greater than an area of the 3-1^{st} opening.

When viewed in a direction perpendicular to the substrate, the 3-1^{st} opening may be disposed in the 1-1^{st} opening.

The substrate may further include a groove corresponding to the 3-1^{st} opening.

A fourth acute angle formed by an inner surface of the groove with respect to the upper surface of the substrate may be the same as or less than the third acute angle.

An inner surface of the groove and the inner surface of the 3-1^{st} opening may form a continuous surface with each other.

The display apparatus of may further include an organic interlayer insulating layer disposed on the third gate insulating layer, and an organic material layer filling the first opening and including a same material as the organic interlayer insulating layer.

According to one or more embodiments, a method of manufacturing a display apparatus may include preparing a substrate including a component area including a transmission area, a main area outside the component area, and a bending area bent based on a bending axis, forming a buffer layer on the substrate, forming a first semiconductor layer on the buffer layer, forming a first gate insulating layer overlapping the first semiconductor layer, and simultaneously forming, in the first gate insulating layer, a 1-1^{st} opening corresponding to the bending area and including a first acute angle formed by an inner surface of the 1-1^{st} opening with respect to an upper surface of the substrate with a 2-1^{st} opening corresponding to the transmission area and including a second acute angle formed by an inner surface of the 2-1^{st} opening with respect to the upper surface of the substrate.

The method may further include forming, in the first gate insulating layer, a 1-1^{st} through-hole exposing a portion of the first semiconductor layer and including a first contact acute angle formed by an inner surface of the 1-1^{st} through-hole with respect to the upper surface of the substrate, wherein the first contact acute angle may be greater than the first acute angle.

The method may further include forming a second gate insulating layer on the first gate insulating layer, forming a second semiconductor layer on the second gate insulating layer, and forming a third gate insulating layer overlapping the second semiconductor layer.

The method may further include forming, in the third gate insulating layer, a 2-1^{st} through-hole exposing a portion of the second semiconductor layer and including a second contact acute angle with respect to the upper surface of the substrate.

The forming of the 2-1^{st} through-hole in the third gate insulating layer may include forming, in the third gate insulating layer, simultaneously with the 2-1^{st} through-hole, a 3-1^{st} opening corresponding to the bending area and including a third acute angle formed by an inner surface of the 3-1^{st} opening with respect to the upper surface of the substrate.

When viewed in a direction perpendicular to the substrate, an area of the 1-1^{st} opening may be greater than an area of the 3-1^{st} opening.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a portion of a display apparatus according to an embodiment;

FIG. 2 is a schematic side view of a portion of the display apparatus of FIG. 1;

FIG. 3 is a schematic cross-sectional view of the display apparatus of FIG. 1, taken along line I-I′;

FIG. 4 is a schematic circuit diagram of a pixel included in the display apparatus of FIG. 1;

FIG. 5 is a schematic cross-sectional view of the display apparatus of FIG. 1, taken along lines A-A′ and B-B′;

FIG. 6 is a schematic cross-sectional view of a region around a first through-hole of the display apparatus of FIG. 1;

FIG. 7 is a schematic cross-sectional view of a region around a second through-hole of the display apparatus of FIG. 1;

FIG. 8 is a schematic cross-sectional view of regions around a first opening and a third opening of the display apparatus of FIG. 1;

FIG. 9 is a schematic cross-sectional view of regions around a first opening, a third opening, and a groove of the display apparatus of FIG. 1;

FIG. 10 is a schematic cross-sectional view of regions around a second opening and a fourth opening of the display apparatus of FIG. 1;

FIG. 11 is a schematic cross-sectional view of the display apparatus of FIG. 1, taken along lines A-A′ and B-B′;

FIG. 12 is a schematic cross-sectional view of a region around a first through-hole of the display apparatus of FIG. 11;

FIG. 13 is a schematic cross-sectional view of the display apparatus of FIG. 1, taken along line A-A′;

FIG. 14 is a schematic cross-sectional view of regions around a first opening, a third opening, and a groove of the display apparatus of FIG. 1;

FIG. 15 is a schematic cross-sectional view of a region around a first opening of the display apparatus of FIG. 1;

FIG. 16 is a schematic flowchart of a method of manufacturing a display apparatus according to an embodiment; and

FIGS. 17 to 19 are cross-sectional views illustrating processes of forming a first opening and a third opening in the method of FIG. 16, in chronological order.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

In descriptions with reference to the drawings, the same reference numerals are given to components that are the same or substantially the same and redundant descriptions will not be provided.

In embodiments to be described hereinafter, when elements, such as a layer, a film, an area, a plate, etc. are referred to as being “on” another element, the reference may indicate not only a case where the element is “directly on” the other element, but also a case where yet another element is between the element and the other element. Also, for convenience of explanation, elements in the drawings may have exaggerated or reduced sizes. For example, sizes and thicknesses of the elements in the drawings may be randomly indicated for convenience of explanation, and thus, the disclosure is not necessarily limited to the illustrations of the drawings.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

It will be understood that the terms “connected to” or “coupled to” may include a physical or electrical connection or coupling.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

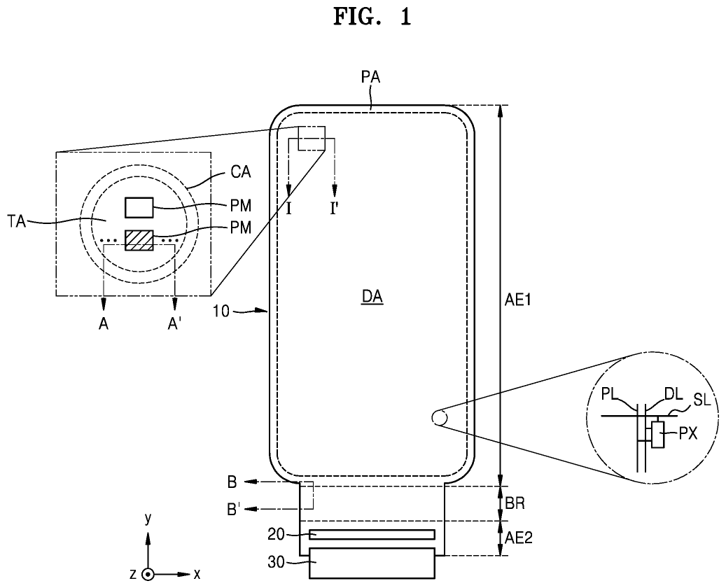

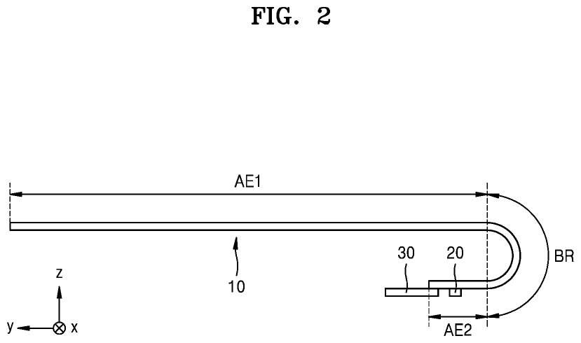

FIG. 1 is a plan view schematically illustrating a portion of a display apparatus according to an embodiment, and FIG. 2 is a side view schematically illustrating a portion of the display apparatus of FIG. 1.

As illustrated in FIGS. 1 and 2, the display apparatus according to an embodiment may include a display panel 10. The display apparatus may include any type of display apparatus that include the display panel 10. For example, the display apparatus may include various products, such as a smartphone, a tablet, a laptop, a television, or an advertising board.

The display panel 10 may include a display area DA and a peripheral area PA outside the display area DA. The display area DA may be an area in which an image is displayed, and multiple main pixels PX may be arranged in the display area DA. Viewed in a direction approximately vertical to the display panel 10, the display area DA may have various shapes including a circular shape, an oval shape, a polygonal shape, a shape of a predetermined or given figure, etc. FIG. 1 illustrates that the display area DA has an approximately rectangular shape with round edges.

The peripheral area PA may be arranged outside the display area DA. A width (in an x-axis direction) of a portion of the peripheral area PA may be less than a width (in the x-axis direction) of the display area DA. Based on this structure, the portion of the peripheral area PA may readily bend, as described below.

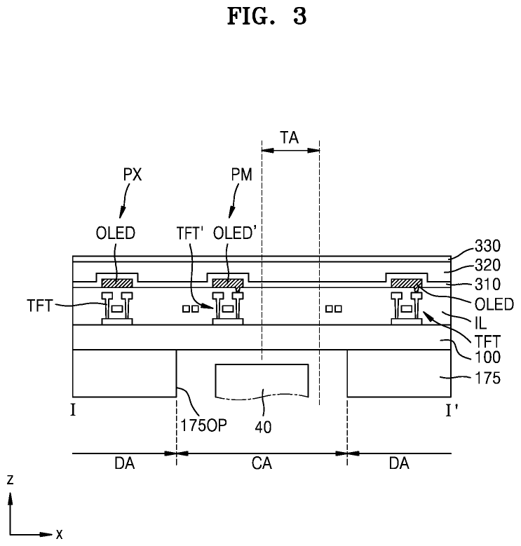

However, because the display panel 10 includes a substrate 100 (FIG. 3 and thereafter) to be described below, it may also be described that the substrate 100 includes the display area DA and the peripheral area PA as described above. Hereinafter, for convenience, it is described that the substrate 100 may include the display area DA and the peripheral area PA.

It may also be understood that the display panel 10 may include a main area AE1, a bending area BR outside the main area AE1, and a sub-area AE2 located (disposed) at the opposite side of the main area AE1 based on the bending area BR. The display panel 10 may be bent in the bending area BR, as illustrated in FIG. 2, and thus, viewed in a z-axis direction, a portion of the sub-area AE2 may overlap the main area AE1. However, the disclosure is not limited to a display apparatus that is bent and may also be applied to a display apparatus that is not bent. The sub-area AE2 may correspond to a non-display area as described below or may include a non-display area. Because the display panel 10 is bent in the bending area BR, the non-display area of the display apparatus may be invisible when the display apparatus is viewed from a front surface (in a −z direction), or, even when the non-display area of the display apparatus is visible, an area of the visible non-display area may be minimized.

A driving chip 20 may be arranged in the sub-area AE2 of the display panel 10. The driving chip 20 may include an integrated circuit for driving the display panel 10. The integrated circuit may include a data driving integrated circuit configured to generate a data signal. However, the disclosure is not limited thereto.

The driving chip 20 may be mounted in the sub-area AE2 of the display panel 10. The driving chip 20 may be mounted on a same plane as a display surface of the display area DA. However, as the display panel 10 is bent in the bending area BR as described above, the driving chip 20 may be located on a rear surface of the main area AE1.

A printed circuit board 30, etc. may be coupled to an end of the sub-area AE2 of the display panel 10. The printed circuit board 30, etc. may be electrically connected to the driving chip 20, etc. through a pad (not shown) of a substrate.

Hereinafter, an organic light-emitting display apparatus is described as an example of the display apparatus according to an embodiment. However, the display apparatus according to an embodiment is not limited thereto. According to another example, the display apparatus according to an embodiment may include an inorganic light-emitting display apparatus, an inorganic electroluminescent (EL) display apparatus, or a quantum dot light-emitting display apparatus. For example, an emission layer of a display element in the display apparatus may include an organic material or an inorganic material. Also, the display apparatus may include the emission layer and a quantum dot layer located on a path of light emitted from the emission layer.

The display area DA may be an area in which an image is displayed, and multiple main pixels PX may be arranged in the display area DA. Each main pixel PX may include a display element, such as an organic light-emitting diode. Each main pixel PX may emit, for example, red, green, or blue light. The main pixel PX may be connected to a pixel circuit including a thin-film transistor, a storage capacitor, etc. The pixel circuit may be connected to a scan line SL configured to transmit a scan signal, a data line DL crossing the scan line SL and configured to transmit a data signal, a driving voltage line PL configured to supply a driving voltage, etc. The scan line SL may extend in an x direction, and the data line DL and the driving voltage line PL may extend in a y direction.

The main pixel PX may emit light having a brightness corresponding to an electrical signal from the pixel circuit electrically connected to the main pixel PX. The display area DA may display a predetermined or given image through the light emitted from the main pixel PX. For reference, it may be defined that the main pixel PX is an emission area emitting any one of red, green, and blue light, as described above.

The main pixels PX may be electrically connected to outer circuits arranged in the peripheral area PA. A scan driving circuit, an emission control driving circuit, a terminal, a driving power supply line, an electrode power supply line, etc. may be arranged in the peripheral area PA. The scan driving circuit may be configured to provide a scan signal to a pixel through a scan line. The emission control driving circuit may be configured to provide an emission control signal to the pixel through an emission control line. The terminal arranged in the peripheral area PA may not be covered by an insulating layer and may be exposed to be electrically connected to the printed circuit board 30. A terminal of the printed circuit board 30 may be electrically connected to the terminal of the display panel 10.

The display area DA may include a component area CA, below which a component including an optical device, etc. is arranged. Multiple auxiliary pixels PM may be arranged in the component area CA. The display apparatus may provide various auxiliary images by using light emitted from the auxiliary pixels PM arranged in the component area CA.

The component area CA may be an area, below which a component, such as an optical device, etc., is arranged, as described below. The component area CA may include a transmission area TA through which light and/or sound output from the component to the outside or proceeding from the outside toward the component are (is) transmitted. In case that infrared rays are transmitted through the component area CA, a light transmittance may be equal to or greater than about 30%. In some sample embodiments, the light transmittance may be equal to or greater than about 50%, about 75%, about 80%, about 85%, or about 90%.

As described above, the component area CA may include the transmission area TA having a predetermined or given light transmittance, and the transmission area TA may correspond to regions of the component area CA, except for a region in which the auxiliary pixels PM are arranged. The number of auxiliary pixels PM arranged in the component area CA may be less than the number of main pixels PX arranged in the main area AE1.

FIG. 3 is a schematic cross-sectional view of the display apparatus of FIG. 1 taken along line I-I′.

As illustrated in FIG. 3, the display apparatus may include the display panel 10 and a component 40 arranged below the display panel 10 to correspond to the component area CA.

The display panel 10 may include the substrate 100 and may further include a bottom protective film 175 arranged below the substrate 100.

The substrate 100 may include glass or polymer resins. The polymer resins may include polyethersulfone, polyacrylate, polyetherimide, polyethylene naphthalate, polyethylene terephthalate, polyphenylene sulfide, polyarylate, polyimide, polycarbonate, cellulose acetate propionate, etc. The substrate 100 including the polymer resins may be flexible, rollable, and/or bendable. The substrate 100 may have a multi-layered structure including a layer including the polymer resins described above and an inorganic layer (not shown).

The display panel 10 may include a circuit layer including main and auxiliary thin film transistors TFT and TFT′, main and auxiliary organic light-emitting diodes OLED and OLED′ as display elements, and an insulating layer IL between the main and auxiliary thin film transistors TFT and TFT′ and the main and auxiliary organic light-emitting diodes OLED and OLED′. The main pixel PX including the main thin-film transistor TFT and the main organic light-emitting diode OLED connected to the main thin-film transistor TFT may be arranged in the main area AE1, and the auxiliary pixel PM including the auxiliary thin-film transistor TFT′ and the auxiliary organic light-emitting diode OLED′ connected to the auxiliary thin-film transistor TFT′ may be arranged in the component area CA.

Also, the transmission area TA in which the auxiliary thin film transistor TFT′ and the display element are not arranged may be arranged in the component area CA. The transmission area TA may be understood as an area through which the light/signal emitted from the component 40 or the light/signal incident into the component 40 is transmitted.

The display elements may be covered by thin-film encapsulation layers 310, 320, and 330. The thin-film encapsulation layers 310, 320, and 330 may include at least one inorganic encapsulation layer and at least one organic encapsulation layer. The thin-film encapsulation layers 310, 320, and 330 may include first and second inorganic encapsulation layers 310 and 330 and an organic encapsulation layer 320 therebetween. The display elements may also be covered by an encapsulation substrate, etc. including a glass material, a main component of which is SiO₂.

The first and second inorganic encapsulation layers 310 and 330 may include one or more inorganic insulating materials from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acryl-based resins, epoxy-based resins, polyimide, polyethylene, etc.

The bottom protective film 175 may be coupled under the substrate 100 to support and protect the substrate 100. The bottom protective film 175 may include an opening 1750P corresponding to the component area CA. Because the bottom protective film 175 may include the opening 1750P, light transmittance of the transmission area TA may be increased. The bottom protective film 175 may include polyethylene terephthalate or polyimide.

Also, multiple components 20 may be arranged in the component area CA. The components 20 may have different functions from one another.

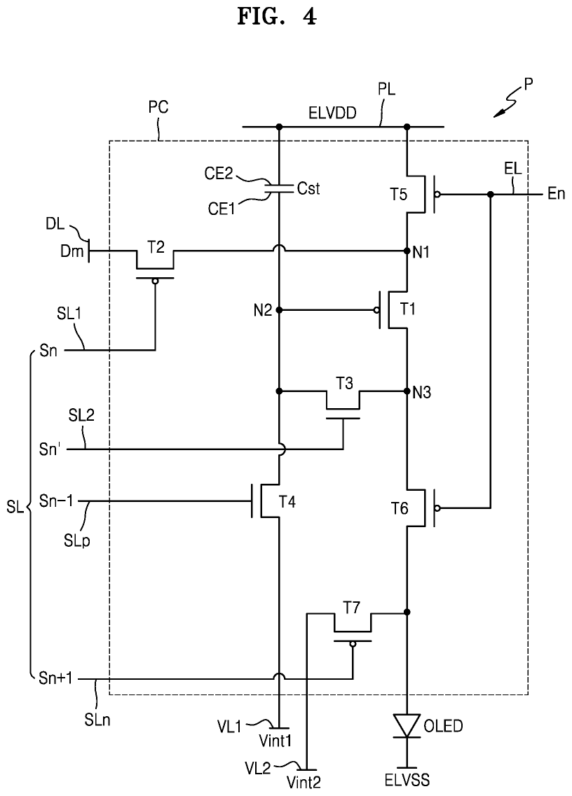

FIG. 4 is a schematic circuit diagram of a pixel included in the display apparatus of FIG. 1.

FIG. 4 shows an equivalent circuit diagram of a pixel P (the main or auxiliary pixel PX or PM) included in the display apparatus of FIG. 1. The pixel P (the main or auxiliary pixel PX or PM) may include thin-film transistors T1 to T7 and a storage capacitor Cst in a pixel circuit PC. The thin-film transistors T1 through T7 and the storage capacitor Cst may be connected to signal lines SL1, SL2, SLp, SLn, EL, and DL, a first initialization voltage line VL1, a second initialization voltage line VL2, and a driving voltage line PL. At least one of these lines described above, for example, the driving voltage line PL, may be shared by adjacent pixels.

The thin-film transistors T1 through T7 may include a driving transistor T1, a switching transistor T2, a compensation transistor T3, a first initialization transistor T4, an operation control transistor T5, an emission control transistor T6, and a second initialization transistor T7.

An organic light-emitting diode OLED may include a first electrode (e.g., a pixel electrode) and a second electrode (e.g., an opposite electrode), and the first electrode of the organic light-emitting diode OLED may be connected to the driving transistor T1 through the emission control transistor T6 and may receive a driving current, and the second electrode may receive a second power voltage ELVSS. The organic light-emitting diode OLED may generate light having a brightness according to the driving current.

One or more of the thin-film transistors T1 through T7 may be provided as n-channel metal-oxide semiconductor field-effect transistors (MOSFETs) (NMOS), and the others may be provided as p-channel MOSFETs (PMOS). For example, the compensation transistor T3 and the first initialization transistor T4 from among the thin-film transistors T1 through T7 may be provided as NMOS transistors, and the others may be provided as PMOS transistors. In other embodiments, the compensation transistor T3, the first initialization transistor T4, and the second initialization transistor T7 from among the thin-film transistors T1 through T7 may be provided as NMOS transistors, and the others may be provided as PMOS transistors. In other embodiments, all of the thin-film transistors T1 through T7 may be provided as NMOS transistors or PMOS transistors. The thin-film transistors T1 through T7 may include amorphous silicon or polysilicon. According to necessity, the NMOS thin-film transistors may include oxide semiconductors. Hereinafter, for convenience, a case in which the compensation transistor T3 and the first initialization transistor T4 are NMOS transistors including oxide semiconductors, and the others are PMOS transistors is described.

The signal lines may include a first scan line SL1 configured to transmit a first scan signal Sn, a second scan line SL2 configured to transmit a second scan signal Sn′, a previous scan line SLp configured to transmit a previous scan signal Sn−1 to the first initialization transistor T4, a next scan line SLn configured to transmit a next scan signal Sn+1 to the second initialization transistor T7, an emission control line EL configured to transmit an emission control signal En to the operation control transistor T5 and the emission control transistor T6, and a data line DL crossing the first scan line SL1 and configured to transmit a data signal Dm.

The driving voltage line PL may be configured to transmit a driving voltage ELVDD to the driving transistor T1, the first initialization voltage line VL1 may be configured to transmit a first initialization voltage Vint1 for initializing the driving transistor T1, and the second initialization voltage line VL2 may be configured to transmit a second initialization voltage Vint2 for initializing the first electrode of the organic light-emitting diode OLED.

A driving gate electrode of the driving transistor T1 may be connected to the storage capacitor Cst via a second node N2. Also, any one of a source area and a drain area of the driving transistor T1 may be connected to the driving voltage line PL through the operation control transistor T5 via a first node N1, and the other may be electrically connected to the first electrode (the pixel electrode) of the organic light-emitting diode OLED through the emission control transistor T6 via a third node N3. The driving transistor T1 may be configured to receive the data signal Dm according to a switching operation of the switching transistor T2 and to supply the driving current to the organic light-emitting diode OLED. For example, according to a voltage applied to the second node N2, the voltage varying according to the data signal Dm, the driving transistor T1 may be configured to control the amount of currents flowing from the first node N1 electrically connected to the driving voltage line PL to the organic light-emitting diode OLED.

A switching gate electrode of the switching transistor T2 may be connected to the first scan line SL1 configured to transmit the first scan signal Sn. Any one of a source area and a drain area of the switching transistor T2 may be connected to the data line DL, and the other may be connected to the driving transistor T1 via the first node N1 and may be connected to the driving voltage line PL through the operation control transistor T5. The switching transistor T2 may be configured to transmit the data signal Dm from the data line DL to the first node N1, according to a voltage applied to the first scan line SL1. For example, the switching transistor T2 may be turned on in response to the first scan signal Sn received through the first scan line SL1 and may be configured to perform a switching operation of transmitting the data signal Dm transmitted through the data line DL to the driving transistor T1 via the first node N1.

A compensation gate electrode of the compensation transistor T3 may be connected to the second scan line SL2. Any one of a source area and a drain area of the compensation transistor T3 may be connected to the first electrode of the organic light-emitting diode OLED through the emission control transistor T6 via the third node N3. The other of the source area and the drain area of the compensation transistor T3 may be connected to a first capacitor electrode CE1 of the storage capacitor Cst and the driving gate electrode of the driving transistor T1 via the second node N2. The compensation transistor T3 may be turned on in response to the second scan signal Sn′ received through the second scan line SL2 and may be configured to diode-connect the driving transistor T1.

A first initialization gate electrode of the first initialization transistor T4 may be connected to the previous scan line SLp. Any one of a source area and a drain area of the first initialization transistor T4 may be connected to the first initialization voltage line VL1. The other of the source area and the drain area of the first initialization transistor T4 may be connected to the first capacitor electrode CE1 of the storage capacitor Cst, the driving gate electrode of the driving transistor T1, etc. via the second node N2. The first initialization transistor T4 may be configured to apply the first initialization voltage Vint1 from the first initialization voltage line VL1 to the second node N2, according to a voltage applied to the previous scan line SLp. For example, the first initialization transistor T4 may be turned on in response to the previous scan signal Sn−1 received through the previous scan line SLp and may be configured to perform an initialization operation of initializing a voltage of the driving gate electrode of the driving transistor T1 by transmitting the initialization voltage Vint1 to the driving gate electrode of the driving transistor T1.

An operation control gate electrode of the operation control transistor T5 may be connected to the emission control line EL, and any one of a source area and a drain area of the operation control transistor T5 may be connected to the driving voltage line PL and the other may be connected to the driving transistor T1 and the switching transistor T2 via the first node N1.

An emission control gate electrode of the emission control transistor T6 may be connected to the emission control line EL, and any one of a source area and a drain area of the emission control transistor T6 may be connected to the driving transistor T1 and the compensation transistor T3 via the third node N3, and the other may be electrically connected to the first electrode (the pixel electrode) of the organic light-emitting diode OLED.

The operation control transistor T5 and the emission control transistor T6 may be simultaneously turned on in response to the emission control signal En received through the emission control line EL so that the driving voltage ELVDD may be transmitted to the organic light-emitting diode OLED, and the driving current may flow in the organic light-emitting diode OLED.

A second initialization gate electrode of the second initialization transistor T7 may be connected to the next scan line SLn, and any one of a source area and a drain area of the second initialization transistor T7 may be connected to the first electrode (the pixel electrode) of the organic light-emitting diode OLED, and the other may be connected to the second initialization voltage line VL2 and may be configured to receive the second initialization voltage Vint2. The second initialization transistor T7 may be turned on in response to the next scan signal Sn+1 received through the next scan line SLn and may be configured to initialize the first electrode (the pixel electrode) of the organic light-emitting diode OLED. The next scan line SLn may be the same as the first scan line SL1. In this case, the corresponding scan line may be configured to transmit the same electrical signal with a time interval to function as the first scan line SL1 and the next scan line SLn. For example, the next scan line SLn may be a first scan line of a pixel adjacent to the main or auxiliary pixel PX or PM and electrically connected to the data line DL.

The second initialization transistor T7 may be connected to the first scan line SL1 as described above. However, the disclosure is not limited thereto, and the second initialization transistor T7 may be connected to the emission control line EL and may be driven according to the emission control signal En.

The storage capacitor Cst may include a first capacitor electrode CE1 and a second capacitor electrode CE2. The first capacitor electrode CE1 of the storage capacitor Cst may be connected to the driving gate electrode of the driving transistor T1 via the second node N2, and the second capacitor electrode CE2 of the storage capacitor Cst may be connected to the driving voltage line PL. The storage capacitor Cst may be configured to store a charge corresponding to a difference between a driving gate electrode voltage of the driving transistor T1 and the driving voltage ELVDD.

A detailed operation of each of the main and auxiliary pixels PX and PM according to an embodiment is described below.

During an initialization period, in case that the previous scan signal Sn−1 is supplied through the previous scan line SLp, the first initialization transistor T4 may be turned on in response to the previous scan signal Sn−1, and the driving transistor T1 may be initialized via the first initialization voltage Vint1 supplied from the first initialization voltage line VL1.

During a data programming period, in case that the first scan signal Sn and the second scan signal Sn′ are supplied through the first scan line SL1 and the second scan line SL2, the switching transistor T2 and the compensation transistor T3 may be turned on in response to the first scan signal Sn and the second scan signal Sn′. Here, the driving transistor T1 may be diode-connected and biased in a forward direction via the compensation transistor T3 that is turned on. A compensation voltage Dm+Vth (Vth is a negative (−) value) obtained by subtracting a threshold voltage Vth of the driving transistor T1 from the data signal Dm supplied from the data line DL may be applied to the driving gate electrode of the driving transistor T1. The driving voltage ELVDD and the compensation voltage Dm+Vth may be applied to both ends of the storage capacitor Cst, and a charge corresponding to a voltage difference between both ends may be stored in the storage capacitor Cst.

During an emission period, the operation control transistor T5 and the emission control transistor T6 may be turned on in response to the emission control signal En supplied from the emission control line EL. A driving current according to a voltage difference between a voltage of the driving gate electrode of the driving transistor T1 and the driving voltage ELVDD may occur, and the driving current may be supplied to the organic light-emitting diode OLED through the emission control transistor T6.

As described above, one or more of the thin-film transistors T1 through T7 may include oxide semiconductors. For example, the compensation transistor T3 and the first initialization transistor T4 may include oxide semiconductors.

Polysilicon is highly reliable, and thus, precisely intended currents may be controlled with respect to flow. Thus, the driving transistor T1 directly affecting brightness of a display apparatus may include a semiconductor layer including polysilicon that is highly reliable, to realize a display apparatus having high resolution. An oxide semiconductor may have a high carrier mobility and a low leakage current, and thus, even in case that a driving time is increased, a voltage drop may be insignificant. For example, in the case of an oxide semiconductor, even during low frequency driving, a color change of an image due to a voltage drop may be insignificant. Accordingly, low frequency driving may be possible. Thus, the compensation transistor T3 and the first initialization transistor T4 may include the oxide semiconductor, to realize a display apparatus in which leakage currents are prevented and power consumption is reduced.

However, the oxide semiconductor is sensitive to light, and thus, the amount of currents may be changed, etc. due to external light. Thus, a metal layer may be arranged below the oxide semiconductor to absorb or reflect the light from the outside. Accordingly, as illustrated in FIG. 3, a gate electrode may be arranged both above and below an oxide semiconductor layer of each of the compensation transistor T3 and the first initialization transistor T4 that include the oxide semiconductor. For example, viewed in a direction (the z-axis direction) vertical to an upper surface 100a of the substrate 100, a metal layer arranged below the oxide semiconductor may overlap the oxide semiconductor.

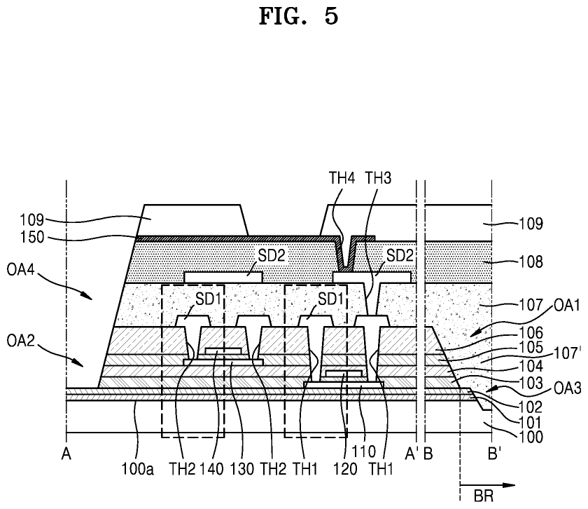

FIG. 5 is a schematic cross-sectional view of the display apparatus of FIG. 1, taken along lines A-A′ and B-B′.

As illustrated in FIG. 5, the display apparatus may include the substrate 100, a barrier layer 101, a buffer layer 102, a first semiconductor layer 110, and a first gate insulating layer 103. Also, the display apparatus may include a second gate insulating layer 104, a second semiconductor layer 130, and a third gate insulating layer 105 and may further include a first organic interlayer insulating layer 107 and a second organic interlayer insulating layer 108.

The substrate 100 may include various materials having a flexible or bendable property, and detailed aspects thereof are the same as or correspond to the descriptions above, and thus, they are not repeatedly described. According to cases, the barrier layer 101 may be arranged on the substrate 100. The barrier layer 101 may prevent the penetration of impurities from the substrate 100, etc. in a direction of the first semiconductor layer 110. The barrier layer 101 may include an inorganic material, such as silicon oxide, silicon nitride, and/or silicon oxynitride.

As described above, the substrate 100 may include the component area CA including the transmission area TA, the main area AE1 outside the component area CA, and the bending area BR bending based on a bending axis.

The buffer layer 102 may be arranged on the substrate 100. In detail, the buffer layer 102 may be arranged on the barrier layer 101. The buffer layer 102 may provide a planarization surface to an upper portion of the substrate 100. Also, the buffer layer 102 may adjust a heat provision speed during a crystallization process for forming the first semiconductor layer 110, so that the semiconductor layer may be uniformly crystallized. The buffer layer 102 may include an inorganic material, such as silicon oxide, silicon nitride, and/or silicon oxynitride.

The first semiconductor layer 110 may be arranged on the buffer layer 102. The first semiconductor layer 110 may include polysilicon and may include a channel area not doped with impurities and a source area and a drain area at both sides of the channel area that are doped with impurities. Here, the impurities may vary according to types of thin-film transistors and may include N-type impurities or P-type impurities.

The first gate insulating layer 103 configured to insulate the first semiconductor layer 110 from a first gate layer 120 may be arranged above the first semiconductor layer 110. The first gate insulating layer 103 may be arranged on the first semiconductor layer 110. The first gate insulating layer 103 may be configured to obtain an insulating property between the first semiconductor layer 110 and the first gate layer 120. The first gate insulating layer 103 may cover (overlap) the first semiconductor layer 110.

The first gate insulating layer 103 may include an inorganic material, such as silicon oxide, silicon nitride, and/or silicon oxynitride, and may be arranged between the semiconductor layer and the gate layer. Also, the first gate insulating layer 103 may have a shape corresponding to the entire surface of the substrate 100 and may have a structure in which through-holes are formed in predetermined or given portions. As described above, the insulating layer including the inorganic material may be formed by chemical vapor deposition (CVD) or atomic layer deposition (ALD). This aspect may likewise be applied to embodiments described below and their modified embodiments.

The first gate insulating layer 103 may have an opening corresponding to the bending area BR, a through-hole exposing a portion of the first semiconductor layer 110, and an opening corresponding to the transmission area TA arranged between the multiple auxiliary pixels PM, and this aspect will be described in detail below.

The first gate layer 120 may be arranged on the first gate insulating layer 103. The first gate layer 120 may be arranged above the first semiconductor layer 110 to overlap the first semiconductor layer 110 and may include at least one metal from among Mo, Al, Pt, Pd, Ag, Mg, Au, Ni, Nd, Ir, Cr, Li, Ca, Ti, W, and Cu.

The second gate insulating layer 104 may be arranged on the first gate layer 120. The second gate insulating layer 104 may cover the first gate layer 120 and may approximately planarize an upper portion of the first gate layer 120. Aspects of the second gate insulating layer 104 that are the same as or correspond to the aspects of the first gate insulating layer 103 may not be described.

The second gate insulating layer 104 may have an opening corresponding to the bending area BR, a through-hole exposing a portion of the first semiconductor layer 110, and an opening corresponding to the transmission area TA, and this aspect will be described in detail below.

The second semiconductor layer 130 may be arranged on the second gate insulating layer 104. Aspects of the second semiconductor layer 130 that are the same as or correspond to the aspects of the first semiconductor layer 110 may not be described. The second semiconductor layer 130 may include an oxide semiconductor layer.

Each of the first semiconductor layer 110 and the second semiconductor layer 130 may be patterned to have a predetermined or given shape, and the patterned second semiconductor layer 130 may not overlap the patterned first semiconductor layer 110 above the patterned first semiconductor layer 110.

The third gate insulating layer 105 may be arranged on the second semiconductor layer 130. Aspects of the third gate insulating layer 105 that are the same as or correspond to the aspects of the first gate insulating layer 103 may not be described.

The third gate insulating layer 105 may have an opening corresponding to the bending area BR, a through-hole included in the first semiconductor layer 110 and penetrating the third gate insulating layer 105, a through-hole exposing a portion of the second semiconductor layer 130, and an opening corresponding to the transmission area TA, and this aspect will be described in detail below.

A second gate layer 140 may be arranged on the third gate insulating layer 105. The second gate layer 140 may be arranged above the second semiconductor layer 130 to overlap the second semiconductor layer 130. The second gate layer 140 may be spaced apart and electrically insulated from the second semiconductor layer 130 by the third gate insulating layer 105.

A fourth gate insulating layer 106 may be arranged on the second gate layer 140, and the fourth gate insulating layer 106 may cover the second gate layer 140 and may approximately planarize an upper portion of the second gate layer 140. Aspects of the fourth gate insulating layer 106 that are the same as or correspond to the aspects of the first gate insulating layer 103 may not be described.

The fourth gate insulating layer 106 may have an opening corresponding to the bending area BR, a through-hole included in the first semiconductor layer 110 and penetrating the fourth gate insulating layer 106, a through-hole included in the second semiconductor layer 130 and penetrating the fourth gate insulating layer 106, and an opening corresponding to the transmission area TA, and this aspect will be described in detail below.

A first conductive layer SD1 may be arranged on the fourth gate insulating layer 106. The first conductive layer SD1 may be connected to the first semiconductor layer 110 or the second semiconductor layer 130 through a first through-hole TH1 or a second through-hole TH2. The first conductive layer SD1 may be patterned to have a predetermined or given shape. The first conductive layer SD1 may include at least one metal from among Mo, Al, Pt, Pd, Ag, Mg, Au, Ni, Nd, Ir, Cr, Li, Ca, Ti, W, and Cu and may include a layered structure including the described metals.

The first conductive layer SD1 may be connected to the first semiconductor layer 110 through the first through-hole TH1. The first through-hole TH1 may penetrate the gate insulating layers (the first gate insulating layer 103 to the fourth gate insulating layer 106) of the display apparatus and may expose a portion of an upper surface of the first semiconductor layer 110 to the outside. The first through-hole TH1 may include multiple sub-through-holes. The first through-hole TH1 may connect the source area and the drain area of the first semiconductor layer 110 to the first conductive layer SD1. However, unlike the illustration of FIG. 5, the first conductive layer SD1 may be connected to only the drain area of the first semiconductor layer 110 through the first through-hole TH1.

Also, the first conductive layer SD1 may be connected to the second semiconductor layer 130 through the second through-hole TH2. The second through-hole TH2 may penetrate the third gate insulating layer 105 and the fourth gate insulating layer 106 and may expose a portion of an upper surface of the second semiconductor layer 130 to the outside. The second through-hole TH2 may include multiple sub-through-holes. The second through-hole TH2 may connect a source area and a drain area of the second semiconductor layer 130 to the first conductive layer SD1. However, unlike the illustration of FIG. 5, the first conductive layer SD1 may be connected to only the drain area of the second semiconductor layer 130 through the second through-hole TH2.

For reference, the sub-through-holes will be described in detail below.

The first organic interlayer insulating layer 107 may be arranged on the first conductive layer SD1, and the first organic interlayer insulating layer 107 may cover the first conductive layer SD1 and may approximately planarize an upper portion of the first conductive layer SD1. The first organic interlayer insulating layer 107 may include, for example, an organic material, such as acryl, benzocyclobutene (BCB), and/or hexamethyldisiloxane (HMDSO). The first organic interlayer insulating layer 107 may include a single layer or layers and may be modified in various ways.

A second conductive layer SD2 may be arranged on the first organic interlayer insulating layer 107, and the second conductive layer SD2 may be connected to the first conductive layer SD1 and/or a pixel electrode to be described below through a third through-hole TH3. The second conductive layer SD2 may be patterned to have a predetermined or given shape. The second conductive layer SD2 may include at least one metal from among Mo, Al, Pt, Pd, Ag, Mg, Au, Ni, Nd, Jr, Cr, Li, Ca, Ti, W, and Cu and may include a layered structure including the described metals. Aspects of the second conductive layer SD2 that are the same as or correspond to the aspects of the first conductive layer SD1 may not be described.

The second organic interlayer insulating layer 108 may be arranged on the second conductive layer SD2, and the second organic interlayer insulating layer 108 may cover the second conductive layer SD2 and may approximately planarize an upper portion of the second conductive layer SD2. The second organic interlayer insulating layer 108 may include, for example, an organic material, such as acryl, BCB, and/or HMDSO. The second organic interlayer insulating layer 108 may include a single layer or layers and may be modified in various ways.

An organic light-emitting diode may be provided on the second organic interlayer insulating layer 108. The organic light-emitting diode may include a pixel electrode 150, an intermediate layer (not shown), and an opposite electrode (not shown).

The pixel electrode 150 may be arranged on the second organic interlayer insulating layer 108. The second organic interlayer insulating layer 108 may be arranged to expose a predetermined or given portion of the second conductive layer SD2 (a drain electrode), rather than covering the entire second conductive layer SD2, and the pixel electrode 150 may be arranged to be connected to the exposed second conductive layer SD2 (e.g., through a fourth through-hole TH4).

A pixel-defining layer 109 including an insulating material may be arranged on the pixel electrode 150. The pixel-defining layer 109 may expose a predetermined or given portion of the pixel electrode 150, and the intermediate layer may be formed on the exposed portion. The pixel-defining layer 109 may include a polyimide or polyacryl-based organic layer. The pixel-defining layer 119 may cover an edge of the pixel electrode 150.

The intermediate layer may be arranged on the pixel electrode 150. The intermediate layer may include a low molecular-weight material or a high molecular-weight material. In case that the intermediate layer includes a low molecular-weight material, the intermediate layer may include a hole injection layer (HIL), a hole transport layer (HTL), an emission layer (EML), an electron transport layer (ETL), and/or an electron injection layer (EIL). In case that the intermediate layer includes a high molecular-weight material, the intermediate layer may, in general, have a structure including an HTL and an EML. These layers may be formed by deposition, inkjet printing, screen printing, laser induced thermal imaging (LITI), or the like.

However, the intermediate layer is not necessarily limited thereto and may have various structures. Also, the intermediate layer may include a layer integrally formed as a single body throughout the multiple pixel electrodes 150 or may include a layer patterned to correspond to each of the pixel electrodes 150.

The opposite electrode may be arranged on the intermediate layer. The opposite electrode may be arranged above a pixel area or the display area DA (FIG. 1), and the opposite electrode may be integrally formed with respect to the multiple organic light-emitting diodes OLED to correspond to the pixel electrodes 150. The opposite electrode may include a transmissive conductive layer including ITO, In₂O₃, or IZO or may also include a transflective layer including a metal, such as Al or Ag. For example, the opposite electrode may include a transflective layer including Mg or Ag.

A spacer (not shown) may further be included on the pixel-defining layer 109, and because the organic light-emitting diode OLED may be readily damaged by external water, oxygen, etc., an encapsulation layer (not shown) may further be provided to cover the organic light-emitting diode OLED to protect the organic light-emitting diode OLED. The encapsulation layer may cover the display area DA and extend to the outside of the display area DA.

An embodiment is described below based on the openings included in the multiple insulating layers 103 to 106 of FIG. 5.

The gate insulating layers 103 to 106 included in the display apparatus according to an embodiment may have a first opening OA1 corresponding to the bending area BR. For example, the first opening OA1 may expose a portion of an upper surface of the buffer layer 102 or a portion of an upper surface of the substrate 100 in the bending area BR to the outside of the gate insulating layers 103 to 106.

The first opening OA1 may be filled with an organic material layer 107′. The organic material layer 107′ may include the same material as the first organic interlayer insulating layer 107 to be described below. For example, the organic material layer 107′ may be simultaneously formed with the first organic interlayer insulating layer 107 below by including the same material as the first organic interlayer insulating layer 107. Furthermore, in case desirable, the organic material layer 107′ may be integrally formed as a single body with the first organic interlayer insulating layer 107. This aspect will be described in detail below.

The gate insulating layers 103 to 106 may have a second opening OA2 corresponding to the transmission area TA. In a manufacturing process, the second opening OA2 may be simultaneously formed with the first opening OA1. The second opening OA2 may expose a portion of the upper surface of the buffer layer 102 in the transmission area TA to the outside of the gate insulating layers 103 to 106.

The second opening OA2 may be filled with another organic material layer (not shown). However, the other organic material layer may include the same material as the organic interlayer insulating layer to be described below or a different material from the organic interlayer insulating layer.

The buffer layer 102 and/or the barrier layer 101 may have a third opening OA3 in the bending area BR. For example, the third opening OA3 may expose a portion of the upper surface of the substrate 100 in the bending area BR to the outside.

As described above, the gate insulating layers 103 to 106 may have the first opening OA1 corresponding to the bending area BR, and the buffer layer 102 and/or the barrier layer 101 may be arranged between the substrate 100 and the first gate insulating layer 103, and thus, the third opening OA3 may be more adjacent to the substrate 100 than the first opening OA1. When viewed in a direction perpendicular to the substrate 100 in a state in which the substrate 100 is not bent, an area of the third opening OA3 may be less than an area of the first opening OA1. Accordingly, a structure including the buffer layer 102 and/or the barrier layer 101 and the gate insulating layers 103 to 106 may have a step difference corresponding to a difference between the first opening OA1 and the third opening OA3.

The first organic interlayer insulating layer 107 and/or the second organic interlayer insulating layer 108 may have a fourth opening OA4 corresponding to the transmission area TA. The fourth opening OA4 may be arranged above the second opening OA2. An inner surface of the fourth opening OA4 may be continuously formed with (extend to) an inner surface of the second opening OA2. The fourth opening OA4 may penetrate the first organic interlayer insulating layer 107 and/or the second organic interlayer insulating layer 108 of the display apparatus. For example, the fourth opening OA4 may expose a portion of the upper surface of the buffer layer 102 in the transmission area TA to the outside through the third opening OA3.

The fourth opening OA4 may be filled with another organic material layer (not shown), and the other organic material layer may include the same material or different material as or from the organic interlayer insulating layer to be described below. However, an additional monomer layer (not shown) may be arranged on the other organic material layer filling the fourth opening OA4.

For reference, multiple sub-openings included in each of the first to fourth openings OA1 to OA4 described above are briefly described below.

As described above, each of the gate insulating layers 103 to 106 may include the sub-opening included in the first opening OA1. For example, the first opening OA1 may include the sub-openings included in the gate insulating layers 103 to 106, respectively.

Each of the gate insulating layers 103 to 106 may include the sub-opening included in the second opening OA2. For example, the second opening OA2 may include the sub-openings included in the gate insulating layers 103 to 106, respectively.

As described above, each of the buffer layer 102 and the barrier layer 101 arranged between the substrate 100 and the gate insulating layers 103 to 106 may include the sub-opening corresponding to the third opening OA3. For example, the sub-opening included in each of the buffer layer 102 and the barrier layer 101 may be included in the third opening OA3. The third opening OA3 may be filled with the same organic material layer as the first opening OA1.

Each of the first organic interlayer insulating layer 107 and the second organic interlayer insulating layer 108 may include the sub-opening corresponding to the fourth opening OA4. For example, the fourth opening OA4 may include the sub-opening included in each of the first organic interlayer insulating layer 107 and the second organic interlayer insulating layer 108.

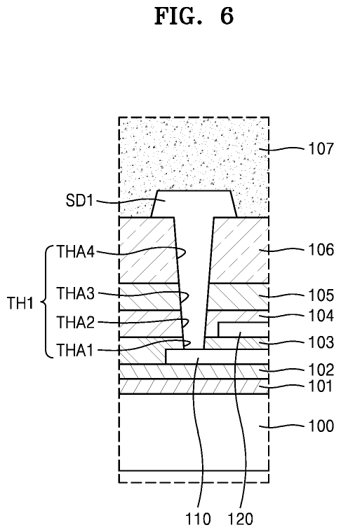

FIG. 6 is a schematic cross-sectional view of a region around the first through-hole TH1 of the display apparatus of FIG. 1.

As illustrated in FIG. 6, the first through-hole TH1 may connect the upper surface of the first semiconductor layer 110 with the first conductive layer SD1. The first through-hole TH1 may include a 1-1^{st} through-hole THA1, a 1-2^{nd} through-hole THA2, a 1-3^{rd} through-hole THA3, and a 1-4^{th} through-hole THA4, as sub-through-holes. For example, with respect to any one of the layers, each sub-through-hole may penetrate the layer.

The first gate insulating layer 103 may include the 1-1^{st} through-hole THA1. The 1-1^{st} through-hole THA1 may expose a portion of the upper surface of the first semiconductor layer 110 to the outside. An inner surface of the 1-1^{st} through-hole THA1 may be continuously formed with an inner surface of the 1-2^{nd} through-hole THA2 to be described below. When viewed in a direction perpendicular to the substrate 100, an area of the 1-1^{st} through-hole THA1 may increase in a direction toward the first gate insulating layer 103 from the substrate 100.

The second gate insulating layer 104 may include the 1-2^{nd} through-hole THA2. The 1-2^{nd} through-hole THA2 may expose a portion of the upper surface of the first semiconductor layer 110 through the 1-1^{st} through-hole THA1. The inner surface of the 1-2^{nd} through-hole THA2 may be continuously formed with the inner surface of the 1-1^{st} through hole THA1 and an inner surface of the 1-3^{rd} through hole THA3 to be described below. When viewed in a direction perpendicular to the substrate 100, an area of the 1-2^{nd} through-hole THA2 may increase in a direction toward the second gate insulating layer 104 from the substrate 100.

The third gate insulating layer 105 may include the 1-3′ through-hole THA3. The 1-3^{rd} through-hole THA3 may expose a portion of the upper surface of the first semiconductor layer 110 through the 1-4^{th} through-hole THA1 and the 1-2^{nd} through-hole THA2. The inner surface of the 1-3^{rd} through-hole THA3 may be continuously formed with the inner surface of the 1-2^{nd} through hole THA2 and an inner surface of the 1-4^{th} through hole THA4 to be described below. When viewed in a direction perpendicular to the substrate 100, an area of the 1-3^{rd} through-hole THA3 may increase in a direction toward the third gate insulating layer 105 from the substrate 100.

The fourth gate insulating layer 106 may include the 1-4^{th} through-hole THA4. The 1-4^{th} through-hole THA4 may expose a portion of the upper surface of the first semiconductor layer 110 through the 1-1^{st} through-hole THA1, the 1-2^{nd} through-hole THA2, and the 1-3^{rd} through-hole THA3. The inner surface of the 1-4^{th} through-hole THA4 may be continuously formed with the inner surface of the 1-3^{rd} through-hole THA3. When viewed in a direction perpendicular to the substrate 100, an area of the 1-4^{th} through-hole THA4 may increase in a direction toward the fourth gate insulating layer 106 from the substrate 100.

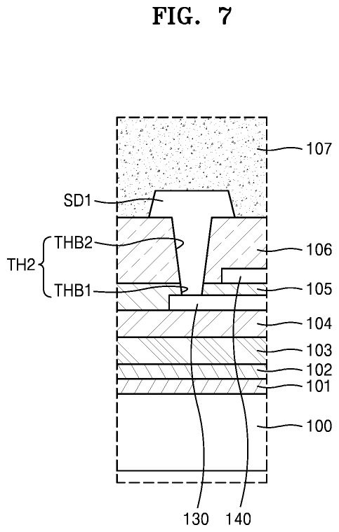

FIG. 7 is a schematic cross-sectional view of a region around the second through-hole TH2 of the display apparatus of FIG. 1.

As illustrated in FIG. 7, the second through-hole TH2 may connect an upper surface of the second semiconductor layer 130 with the first conductive layer SD1. The second through-hole TH2 may include a 2-1^{st} through-hole THB1 and a 2-2^{nd} through-hole THB2 as sub-through-holes. For example, with respect to any one of the layers, each sub-through-hole may penetrate the layer.

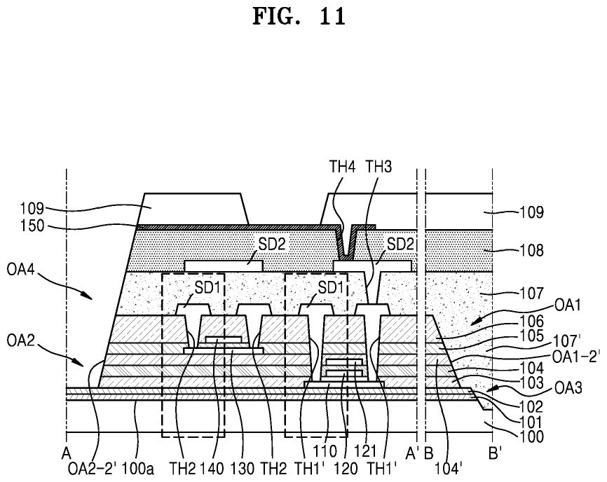

In case that an inorganic insulating layer 104′ (FIG. 11) is additionally provided between the second semiconductor layer 130 and the first conductive layer SD1, the second through-hole TH2 may further include an additional sub-through-hole corresponding to the additional inorganic insulating layer 104′.

The third gate insulating layer 105 may include the 2-1^{st} through-hole THB1. The 2-1^{st} through-hole THB1 may expose a portion of the upper surface of the second semiconductor layer 130 to the outside. An inner surface of the 2-1^{st} through-hole THB1 may be continuously formed with an inner surface of the 2-2^{nd} through-hole THB2. When viewed in a direction perpendicular to the substrate 100, an area of the 2-1^{st} through-hole THB1 may increase in a direction toward the third gate insulating layer 105 from the substrate 100.

The fourth gate insulating layer 106 may include the 2-2^{nd} through-hole THB2. The 2-2^{nd} through-hole THA2 may expose a portion of the upper surface of the second semiconductor layer 130 through the 2-1^{st} through-hole THB1. The inner surface of the 2-2^{nd} through-hole THB2 may be continuously formed with the inner surface of the 2-1^{st} through-hole THB1. When viewed in a direction perpendicular to the substrate 100, an area of the 2-2^{nd} through-hole THB2 may increase in a direction toward the fourth gate insulating layer 106 from the substrate 100.

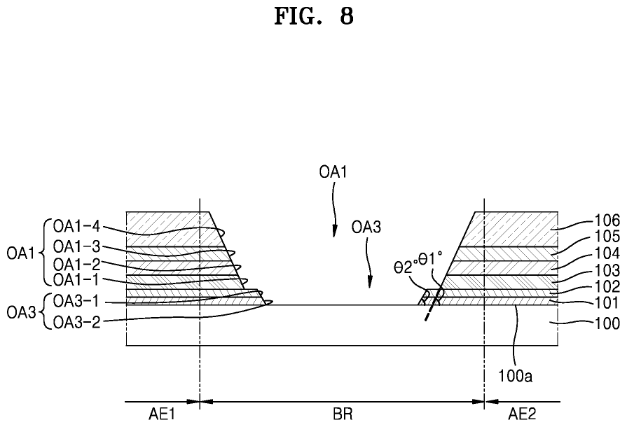

FIG. 8 is a schematic cross-sectional view of regions around the first opening OA1 and the third opening OA3 of the display apparatus of FIG. 1.

As illustrated in FIG. 8, the first opening OA1 may be arranged in the bending area BR. For example, the first opening OA1 may correspond to the bending area BR. The first opening OA1 may be connected to the third opening OA3 formed where a portion of the buffer layer 102 (or the buffer layer 102 and the barrier layer 101) is removed, thus to extend to the upper surface of the substrate 100.

The first opening OA1 may include a 1-1^{st} opening OA1-1, a 1-2^{nd} opening OA1-2, a 1-3^{rd} opening OA1-3, and a 1-4^{th} opening OA1-4 as the sub-openings. The number of sub-openings is not limited thereto, and in case that an inorganic insulating layer is additionally provided between the buffer layer 102 and the first conductive layer SD1, a sub-opening may be additionally provided to correspond to the additional inorganic insulating layer.

When viewed in a direction perpendicular to the substrate 100, an area of the first opening OA1 may increase in a direction toward the first gate insulating layer 103 from the upper surface of the substrate 100. This characteristic with respect to the area of the first opening OA1 may reduce the stress applied to the gate insulating layer in case that the bending area BR is bent.

The first gate insulating layer 103 may include the 1-1^{st} opening OA1-1. The 1-1^{st} opening OA1-1 may expose a portion of the upper surface of the buffer layer 102 or a portion of the upper surface of the substrate 100 to the outside. An inner surface of the 1-1^{st} opening OA1-1 may be continuously formed with an inner surface of the 1-2^{nd} opening OA1-2 to be described below. When viewed in a direction perpendicular to the substrate 100, an area of the 1-1^{st} opening OA1-1 may increase in a direction toward the first gate insulating layer 103 from the substrate 100. The inner surface of the 1-1^{st} opening OA1-1 may form a step difference with an inner surface of a 3-1^{st} opening OA3-1 to be described below.

The 1-1^{st} opening OA1-1 may include the inner surface having a taper angle. An acute angle formed by the inner surface of the 1-1^{st} opening OA1-1 with respect to the upper surface of the substrate 100 may be a first acute angle θ1°. Also, as described below, all of the inner surfaces of the 1-1^{st} opening OA1-1 to the 1-4^{th} opening OA1-4 may be continuously formed, and thus, the first acute angle θ1° of the 1-1^{st} opening OA1-1 may be understood as the same as an acute angle between the inner surface of the first opening OA1 and the upper surface of the substrate 100.

On the contrary, to look at a case where the first opening OA1 is simultaneously formed with the first through-hole TH1, the first opening OA1 may have to have the first acute angle θ1° that is a less taper angle than that of the first through-hole TH1, and thus, an additional slit mask may be needed to form the first opening OA1. However, in case that the slit mask is used to form the first opening OA1, due to diffraction, a portion of the fourth gate insulating layer 106, which is an inorganic insulating layer around the first opening OA1, may also be removed.

Thus, in case that the first opening OA1 and the second opening OA2 are simultaneously manufactured, the problem described above may be solved, and the first opening OA1 may be formed to have the first acute angle θ1° that is a further less taper angle. In case that the first opening OA1 having the first acute angle θ1° that is a lower taper angle is formed, effects of stress on the display apparatus according to the disclosure, the stress being caused by bending of the bending area BR, may be reduced.

Also, the first acute angle θ1° may be the same as a second acute angle θ4° to be described below. For reference, in this disclosure, the meaning of “the same” shall be understood as “the same” in an error range occurring in measurement or “the same” in a normal error range in a manufacturing process.

The second gate insulating layer 104 may include the 1-2^{nd} opening OA1-2. The 1-2^{nd} opening OA1-2 may expose a portion of the upper surface of the buffer layer 102 or a portion of the upper surface of the substrate 100 to the outside through the 1-1^{st} opening OA1-1. The inner surface of the 1-2^{nd} opening OA1-2 may be continuously formed with the inner surface of the 1-1^{st} opening OA1-1 and the inner surface of the 1-3^{rd} opening OA1-3 to be described below. When viewed in a direction perpendicular to the substrate 100, an area of the 1-2^{nd} opening OA1-2 may increase in a direction toward the second gate insulating layer 104 from the substrate 100.

The third gate insulating layer 105 may include the 1-3′ opening OA1-3. The 1-3^{rd} opening OA1-3 may expose a portion of the upper surface of the buffer layer 102 or a portion of the upper surface of the substrate 100 to the outside through the 1-1^{st} opening OA1-1 and the 1-2^{nd} opening OA1-2. The inner surface of the 1-3^{rd} opening OA1-3 may be continuously formed with the inner surface of the 1-2^{nd} opening OA1-2 and the inner surface of the 1-4^{th} opening OA1-4 to be described below. When viewed in a direction perpendicular to the substrate 100, an area of the 1-3^{rd} opening OA1-3 may increase in a direction toward the third gate insulating layer 105 from the substrate 100.

The fourth gate insulating layer 106 may include the 1-4^{th} opening OA1-4. The 1-4^{th} opening OA1-4 may expose a portion of the upper surface of the buffer layer 102 or a portion of the upper surface of the substrate 100 to the outside through the 1-1^{st} opening OA1-1, the 1-2^{nd} opening OA1-2, and the 1-3^{rd} opening OA1-3. The inner surface of the 1-4^{th} opening OA1-4 may be continuously formed with the inner surface of the 1-3^{rd} opening OA1-3. When viewed in a direction perpendicular to the substrate 100, an area of the 1-4^{th} opening OA1-4 may increase in a direction toward the fourth gate insulating layer 106 from the substrate 100.

As illustrated in FIG. 8, the third opening OA3 may be arranged in the bending area BR and may be arranged below the first opening OA1. For example, the third opening OA3 may correspond to the bending area BR, and when viewed in a direction perpendicular to the substrate 100, the third opening OA3 may be arranged in the first opening OA1. An inner surface of the third opening OA3 may form a step difference with the inner surface of the first opening OA1.

The third opening OA3 may include the 3-1^{st} opening OA3-1 and a 3-2^{nd} opening OA3-2 as the sub-openings. The number of sub-openings is not limited thereto, and in case that a layer is further provided between the substrate 100 and the buffer layer 102, a sub-opening may be additionally provided to correspond to the additional layer.

Hereinafter, the third opening OA3 described in this specification may be a component that is simultaneously formed with the second through-hole TH2 in the main area AE1, and the third opening OA3 may be formed together with the second through-hole TH2 in an etching process for forming the second through-hole TH2.

When viewed in a direction perpendicular to the substrate 100, an area of the third opening OA3 may increase in a direction toward the buffer layer 102 from the upper surface of the substrate 100. This characteristic with respect to the area of the third opening OA3 may reduce the stress applied to the buffer layer 102 and the barrier layer 101 in case that the bending area BR is bent.

The buffer layer 102 may include the 3-1^{st} opening OA3-1. The 3-1^{st} opening OA3-1 may expose a portion of the upper surface of the substrate 100 to the outside through the 3-2^{nd} opening OA3-2 to be described below. The inner surface of the 3-1^{st} opening OA3-1 may be continuously formed with an inner surface of the 3-2^{nd} opening OA3-2 to be described below.

When viewed in a direction perpendicular to the substrate 100, an area of the 3-1^{st} opening OA3-1 may increase in a direction toward the buffer layer 102 from the substrate 100. The inner surface of the 3-1^{st} opening OA3-1 may form a step difference with the inner surface of the 1-1^{st} opening OA1-1 described above. When viewed in a direction perpendicular to the substrate 100, the 3-1^{st} opening OA3-1 may be arranged in the 1-1^{st} opening OA1-1.

The barrier layer 101 may include the 3-2^{nd} opening OA3-2. The 3-2^{nd} opening OA3-2 may be arranged below the 3-1^{st} opening OA3-1. The 3-2^{nd} opening OA3-2 may expose a portion of the upper surface of the substrate 100 to the outside. The 3-2^{nd} opening OA3-2 may be arranged below the 3-1^{st} opening OA3-1, and the inner surface of the 3-2^{nd} opening OA3-2 may be continuously formed with the inner surface of the 3-1^{st} opening OA3-1.

When viewed in a direction perpendicular to the substrate 100, an area of the 3-2^{nd} opening OA3-2 may increase in a direction toward the barrier layer 101 from the substrate 100. When viewed in a direction perpendicular to the substrate 100, the 3-2^{nd} opening OA3-2 may be arranged in the 1-1^{st} opening OA1-1.

The 3-1^{st} opening OA3-1 may include the inner surface having a taper angle. An acute angle formed by the inner surface of the 3-1^{st} opening OA1-1 with respect to the upper surface of the substrate 100 may be a third acute angle θ2°. Also, as described below, the inner surfaces of both of the 3-1^{st} opening OA3-1 and the 3-2^{nd} opening OA3-2 may be continuously formed with each other, and thus, the third acute angle θ2° of the 3-1^{st} opening OA3-1 may also be understood as the same as an acute angle between the inner surface of the third opening OA3 and the upper surface of the substrate 100. Here, the third acute angle θ2° may be less than the first acute angle θ1°.

The third opening OA3 may be formed after the first opening OA1 is formed, and thus, the third opening OA3 may be formed by using a slit mask to have the third acute angle θ2° that is a relatively less taper angle. Also, the third opening OA3 may be simultaneously formed with the second through-hole TH2, and thus, the third opening OA3 may be formed without adding an additional etching process. Thus, the process costs and time may be saved.

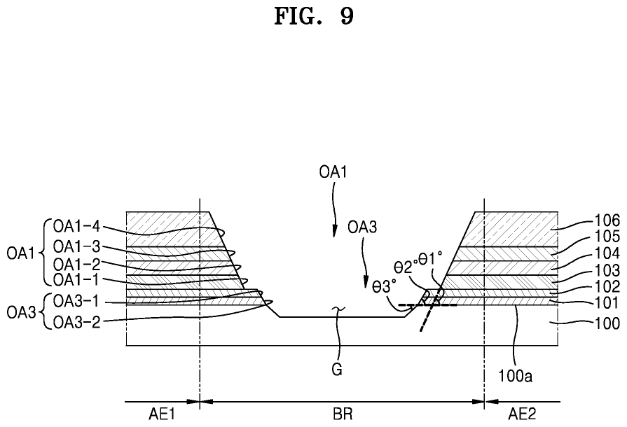

FIG. 9 is a schematic cross-sectional view of regions around the first opening OA1, the third opening OA3, and a groove G of the display apparatus of FIG. 1.

As illustrated in FIG. 9, the first opening OA1, the third opening OA3 below the first opening OA1, and the groove G below the third opening OA3 may be arranged in the bending area BR. Descriptions about the first opening OA1 and the third opening OA3 are the same as or correspond to the descriptions given above, and thus, may be omitted.

The substrate 100 may include the groove G arranged below the third opening OA3. The groove G may be arranged in the bending area BR and may be arranged below the third opening OA3. For example, the groove G may correspond to the bending area BR, and when viewed in a direction perpendicular to the substrate 100, the groove G may be arranged in the first opening OA1 and the third opening OA3. The groove G may be formed by removing a portion of the upper surface of the substrate 100.

The groove G may include an inner surface having a taper angle. An acute angle formed by the inner surface of groove G with respect to the upper surface of the substrate 100 may be a fourth acute angle θ3°. Here, the fourth acute angle θ3° may be the same as or less than the third acute angle θ2°.

The groove G may be formed by an ashing process for removing residue gas used for etching, after the etching process for forming the third opening OA3. That is because compared to the effect of an etching process for removing the multiple gate insulating layers, the effect of an ashing process for removing the substrate 100 may be smaller.

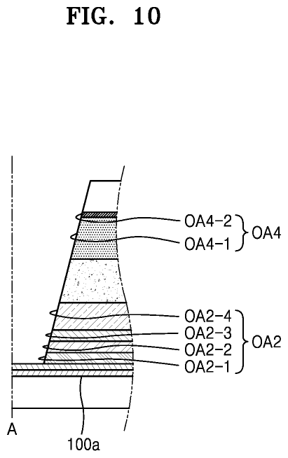

FIG. 10 is a schematic cross-sectional view of regions around the second opening OA2 and the fourth opening OA4 of the display apparatus of FIG. 1.

As illustrated in FIG. 10, the second opening OA2 may be arranged in the transmission area TA. For example, the second opening OA2 may correspond to the transmission area TA.

The second opening OA2 may extend to the upper surface of the buffer layer 102 and may be connected to the fourth opening OA4 formed by removing the first organic interlayer insulating layer 107 and the second organic interlayer insulating layer 108 arranged on the gate insulating layers 103 to 106 to expose a portion of the upper surface of the buffer layer 102 to the outside.

The second opening OA2 may include a 2-1^{st} opening OA2-1, a 2-2^{nd} opening OA2-2, a 2-3^{rd} opening OA2-3, and a 2-4^{th} opening OA2-4 as the sub-openings. The number of sub-openings is not limited thereto, and in case that an inorganic insulating layer is additionally provided between the buffer layer 102 and the first conductive layer SD1, a sub-opening may be additionally provided to correspond to the additional inorganic insulating layer. When viewed in a direction perpendicular to the substrate 100, an area of the second opening OA2 may increase in a direction toward the first gate insulating layer 103 from the upper surface of the substrate 100.

The first gate insulating layer 103 may include the 2-1^{st} opening OA2-1. The 2-1^{st} opening OA2-1 may expose a portion of the upper surface of the buffer layer 102 to the outside. An inner surface of the 2-1^{st} opening OA2-1 may be continuously formed with an inner surface of the 2-2^{nd} opening OA2-2 to be described below. When viewed in a direction perpendicular to the substrate 100, an area of the 2-1^{st} opening OA2-1 may increase in a direction toward the first gate insulating layer 103 from the substrate 100. Also, the 2-1^{st} opening OA2-1 may include the inner surface having a taper angle, and this aspect will be described below.

The second gate insulating layer 104 may include the 2-2^{nd} opening OA2-2. The 2-2^{nd} opening OA2-2 may expose a portion of the upper surface of the buffer layer 102 through the 2-1^{st} opening OA2-1. The inner surface of the 2-2^{nd} opening OA2-2 may be continuously formed with the inner surface of the 2-1^{st} opening OA2-1 and an inner surface of the 2-3^{rd} opening OA2-3 to be described below. When viewed in a direction perpendicular to the substrate 100, an area of the 2-2^{nd} opening OA2-2 may increase in a direction toward the second gate insulating layer 104 from the substrate 100.

The third gate insulating layer 105 may include the 2-3^{rd} opening OA2-3. The 2-3^{rd} opening OA2-3 may expose a portion of the upper surface of the buffer layer 102 to the outside through the 2-1^{st} opening OA2-1 and the 2-2^{nd} opening OA2-2. The inner surface of the 2-3^{rd} opening OA2-3 may be continuously formed with the inner surface of the 2-2^{nd} opening OA2-2 and an inner surface of the 2-4^{th} opening OA2-4 to be described below. When viewed in a direction perpendicular to the substrate 100, an area of the 2-3^{rd} opening OA2-3 may increase in a direction toward the third gate insulating layer 105 from the substrate 100.

The fourth gate insulating layer 106 may include the 2-4^{th} opening OA2-4. The 2-4^{th} opening OA2-4 may expose a portion of the upper surface of the buffer layer 102 to the outside through the 2-1^{st} opening OA2-1, the 2-2^{nd} opening OA2-2, and the 2-3^{rd} opening OA2-3. The inner surface of the 2-4^{th} opening OA2-4 may be continuously formed with the inner surface of the 2-3^{rd} opening OA2-3. When viewed in a direction perpendicular to the substrate 100, an area of the 2-4^{th} opening OA2-4 may increase in a direction toward the fourth gate insulating layer 106 from the substrate 100.

As illustrated in FIG. 10, the fourth opening OA4 may be arranged in the transmission area TA and may be arranged above the second opening OA2. For example, the fourth opening OA4 may correspond to the transmission area TA, and the inner surface of the fourth opening OA4 may be continuously formed with the inner surface of the second opening OA2.

The fourth opening OA4 may extend to the upper surface of the buffer layer 102 through the second opening OA2 and may be formed by removing the first organic interlayer insulating layer 107 and the second organic interlayer insulating layer 108 arranged on the inorganic insulating layer. The fourth opening OA4 may include a 4-1^{st} opening OA4-1 and a 4-2^{nd} opening OA4-2 as the sub-openings. The number of sub-openings is not limited thereto, and in case that an organic interlayer insulating layer is additionally provided between the first conductive layer SD1 and the pixel electrode 150, a sub-opening may be additionally provided to correspond to the additional organic interlayer insulating layer. When viewed in a direction perpendicular to the substrate 100, an area of the fourth opening OA4 may increase in a direction toward the first organic interlayer insulating layer 107 from the upper surface of the substrate 100.

The first interlayer insulating layer 107 may include the 4-1^{st} opening OA4-1. The 4-1^{st} opening OA4-1 may expose a portion of the upper surface of the buffer layer 102 through the second opening OA2. An inner surface of the 4-1^{st} opening OA4-1 may be continuously formed with the inner surface of the 2-4^{th} opening OA2-2 described above and an inner surface of the 4-2^{nd} opening OA4-2 to be described below. When viewed in a direction perpendicular to the substrate 100, an area of the 4-1^{st} opening OA4-1 may increase in a direction toward the first organic interlayer insulating layer 107 from the substrate 100.

The second organic interlayer insulating layer 108 may include the 4-2^{nd} opening OA4-2. The 4-2^{nd} opening OA4-2 may expose a portion of the upper surface of the buffer layer 102 to the outside through the 4-1^{st} opening OA4-1 and the second opening OA2. The inner surface of the 4-2^{nd} opening OA4-2 may be continuously formed with the inner surface of the 4-1^{st} opening OA4-1. When viewed in a direction perpendicular to the substrate 100, an area of the 4-2^{nd} opening OA4-2 may increase in a direction toward the second organic interlayer insulating layer 108 from the substrate 100.

For reference, in the drawings illustrating the second opening OA2 and the fourth opening OA4 in the component area CA, such as FIG. 10, etc., only the inner surfaces at one side are illustrated, for convenience. However, referring to the component area CA illustrated in FIG. 1, it may be obvious that according to the disclosure described in the specification, an inner surface at another side of each of the second opening OA2 and the fourth opening OA4 may have the same structure as the inner surface at a side described above.

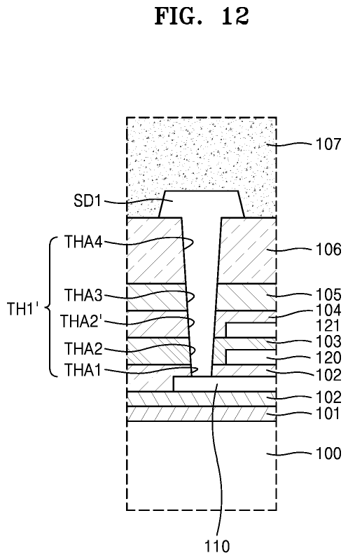

FIG. 11 is a schematic cross-sectional view of the display apparatus of FIG. 1 taken along lines A-A′ and B-B′, and FIG. 12 is a schematic cross-sectional view of a region around the first through-hole TH1′ of the display apparatus of FIG. 11.

As illustrated in FIG. 11, the display apparatus may further include an additional gate layer 121 arranged on the second gate insulating layer 104 and an additional gate insulating layer 104′ covering the additional gate layer 121.

The additional gate layer 121 may be arranged above the first gate layer 120 to overlap the first gate layer 120 and may include at least one metal from among Mo, Al, Pt, Pd, Ag, Mg, Au, Ni, Nd, Jr, Cr, Li, Ca, Ti, W, and Cu.

While the additional gate layer 121 may overlap the first gate layer 120 above the first gate layer 120, the additional gate layer 121 may be spaced apart from the first gate layer 120 by the second gate insulating layer 104. For example, the additional gate layer 121 may be spaced apart from the first gate layer 120 and may function as the storage capacitor Cst.

The additional gate insulating layer 104′ may include an inorganic material, such as silicon oxide, silicon nitride, and/or silicon oxynitride, and may be arranged between the first gate layer 120 and the second semiconductor layer 130. Also, the additional gate insulating layer 104′ may have a shape corresponding to the entire surface of the substrate 100 and may have a structure in which through-holes are formed in predetermined or given portions. As described above, the insulating layer including an inorganic material may be formed by CVD or ALD. This aspect may be likewise applied to embodiments described below and their modified embodiments.

The additional gate insulating layer 104′ may have a first additional opening OA1-2′ corresponding to the bending area BR, an additional through-hole THAT (FIG. 12) exposing a portion of the first semiconductor layer 110, and a second additional opening OA2-2′ corresponding to the transmission area TA. The first additional opening OA1-2′ and the second additional opening OA2-2′ may correspond to the additional through-hole THAT.

The additional gate insulating layer 104′ may be arranged on the second gate insulating layer 104 and may be arranged below the third gate insulating layer 105 to cover the additional gate layer 121. For example, the additional gate insulating layer 104′ may be arranged between the second gate insulating layer 104 and the third gate insulating layer 105.

In other words, the first opening OA1 may further include, between the 1-2^{nd} opening OA1-2 and the 1-3^{rd} opening OA1-3, the first additional opening OA1-2′ included in the additional gate insulating layer 104′, as the sub-opening. The second opening OA2 may further include, between the 2-2^{nd} opening OA2-2 and the 2-3^{rd} opening OA2-3, the second additional opening OA2-2′ included in the additional gate insulating layer 104′, as the sub-opening.

The additional gate insulating layer 104′ may include the first additional opening OA1-2′. The first additional opening OA1-2′ may be arranged in the bending area BR and may penetrate the additional gate insulating layer 104′. The first additional opening OA1-2; may expose a portion of the upper surface of the buffer layer 102 or a portion of the upper surface of the substrate 100 to the outside through the 1-1^{st} opening OA1-1 and the 1-2^{nd} opening OA1-2. An inner surface of the first additional opening OA1-2′ may be continuously formed with the inner surface of the 1-2^{nd} opening OA1-2 and the inner surface of the 1-3^{rd} opening OA1-3. When viewed in a direction perpendicular to the substrate 100, an area of the first additional opening OA1-2′ may increase in a direction toward the additional gate insulating layer 104′ from the substrate 100.

The additional gate insulating layer 104′ may include the second additional opening OA2-2′. The second additional opening OA2-2′ may be arranged in the transmission area TA and may penetrate the additional gate insulating layer 104′. The second additional opening OA2-2′ may expose a portion of the upper surface of the buffer layer 102 to the outside through the 2-1^{st} opening OA2-1 and the 2-2^{nd} opening OA2-2. An inner surface of the second additional opening OA2-2′ may be continuously formed with the inner surface of the 2-2^{nd} opening OA2-2 and the inner surface of the 2-3^{rd} opening OA2-3. When viewed in a direction perpendicular to the substrate 100, an area of the second additional opening OA2-2′ may increase in a direction toward the additional gate insulating layer 104′ from the substrate 100.

As illustrated in FIG. 12, the first through-hole TH1 may further include, between the 1-2^{nd} through-hole THA2 and the 1-3^{rd} through-hole THA3, the additional through-hole THA2′ included in the additional gate insulating layer 104′, as the sub-through-hole. The first through-hole TH1 may be configured to penetrate the first to fourth gate insulating layers 103 to 106 and connect the first conductive layer SD1 to the first semiconductor layer 110.

In other words, the additional gate insulating layer 104′ may include the additional through-hole THA2′. The additional through-hole THA2′ may be arranged in the main area AE1 and may penetrate the additional gate insulating layer 104′. The additional through-hole THA2′ may expose a portion of the upper surface of the first semiconductor layer 110 through the 1-1′ through-hole THA1 and the 1-2^{nd} through-hole THA2. An inner surface of the additional through-hole THA2′ may be continuously formed with the inner surface of the 1-2^{nd} through hole THA2 and the inner surface of the 1-3^{rd} through hole THA3. When viewed in a direction perpendicular to the substrate 100, an area of the additional through-hole THA2′ may increase in a direction toward the additional gate insulating layer 104′ from the substrate 100.

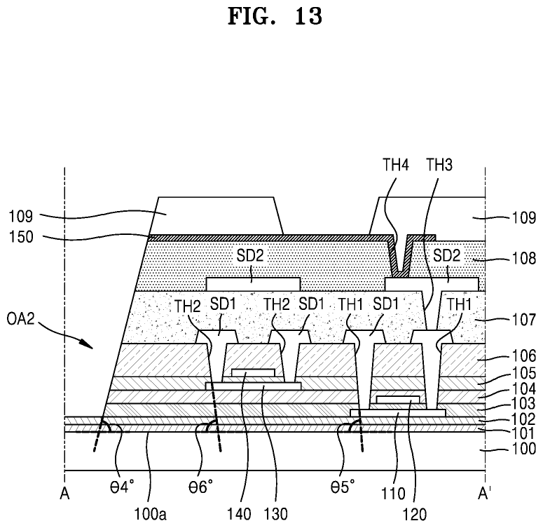

FIG. 13 is a schematic cross-sectional view of the display apparatus of FIG. 1, taken along line A-A′.

As illustrated in FIG. 13, the inner surface of the second opening OA2 may have a second acute angle θ4° with respect to the upper surface of the substrate 100. For example, the inner surface of the second opening OA2 may be inclined in an external direction from a center of the second opening OA2 by the second acute angle θ4° with respect to the upper surface of the substrate 100. Here, the second acute angle θ4° may have the same size as the first acute angle θ1° described above. That is because the second opening OA2 and the first opening OA1 may be simultaneously manufactured by the same process.

The inner surface of the first through-hole TH1 may have a first contact acute angle θ5° with respect to the upper surface of the substrate 100. For example, the inner surface of the first through-hole TH1 may be inclined in an external direction from a center of the first through-hole TH1 by the first contact acute angle θ5° with respect to the upper surface of the substrate 100. Here, the first contact acute angle θ5° may be greater than the first acute angle θ1° described above. That is because the first through-hole TH1 and the first opening OA1 may be manufactured by different processes from each other, and the first through-hole TH1 may have to be formed to be narrow and deep to connect the first conductive layer SD1 to the first semiconductor layer 110. Also, the first through-hole TH1 and the second opening OA2 may also be manufactured by different processes from each other, and thus, for the same reason, the first contact acute angle θ5° may be greater than the second acute angle θ4° described above.

The inner surface of the second through-hole TH2 may have a second contact acute angle θ6° with respect to the upper surface of the substrate 100. For example, the inner surface of the second through-hole TH2 may be inclined in an external direction from a center of the second through-hole TH2 by the second contact acute angle θ6° with respect to the upper surface of the substrate 100. Here, the second contact acute angle θ6° may be greater than the first acute angle θ1° described above. That is because the second through-hole TH2 and the first opening OA1 may be manufactured by different processes from each other, and the second through-hole TH1 may have to be formed to be narrow and deep to connect the first conductive layer SD1 to the second semiconductor layer 130. Also, the second through-hole TH2 and the second opening OA2 may also be manufactured by different processes from each other, and thus, for the same reason, the second contact acute angle θ6° may be greater than the second acute angle θ4° described above.

The second contact acute angle θ6° may be greater than the third acute angle θ2° of the third opening OA3 described above. However, the second through-hole TH2 and the third opening OA3 may be simultaneously manufactured by the same process. Although the second through-hole TH2 and the third opening OA3 may be simultaneously manufactured, the second contact acute angle θ6° may be greater than the third acute angle θ2°. For example, the third acute angle θ2° may be less than the second contact acute angle θ6°.

Here, in case forming the third opening OA3, a slit mask may be used for a portion in which the third opening OA3 is to be formed. Unlike the first opening OA1, the third opening OA3 may be formed after the first opening OA1 is formed, and thus, there are seldom effects on the fourth gate insulating layer 106, etc. even in case that the slit mask is used.

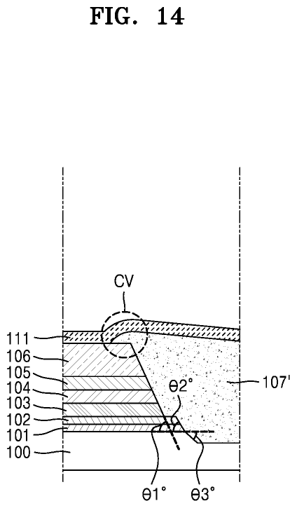

FIG. 14 is a schematic cross-sectional view of regions around the first opening OA1, the third opening OA3, and the groove G of the display apparatus of FIG. 1.

As illustrated in FIG. 14, the first opening OA1 and the third opening OA3 may be filled with the organic material layer 107′. As described above, the organic material layer 107′ may include the same material as the first organic interlayer insulating layer 107.

A line layer 111 configured to connect the driving chip to the display panel in the bending area BR may be arranged on the organic material layer 107′. The line layer 111 may include at least one metal from among Mo, Al, Pt, Pd, Ag, Mg, Au, Ni, Nd, Jr, Cr, Li, Ca, Ti, W, and Cu. Also, the line layer 111 may have a multi-layered structure, for example, a Ti/Al/Ti multi-layered structure.

The organic material layer 107′ may cover the inner surface of the first opening OA1. Also, a portion CV of the organic material layer 107′ may protrude to the outside of the first opening OA1 to cover an end of the fourth gate insulating layer 106. A shape of the line layer 111 may correspond to a shape of the portion CV of the organic material layer 107′, the portion CV covering the end of the fourth gate insulating layer 106 and being convex.

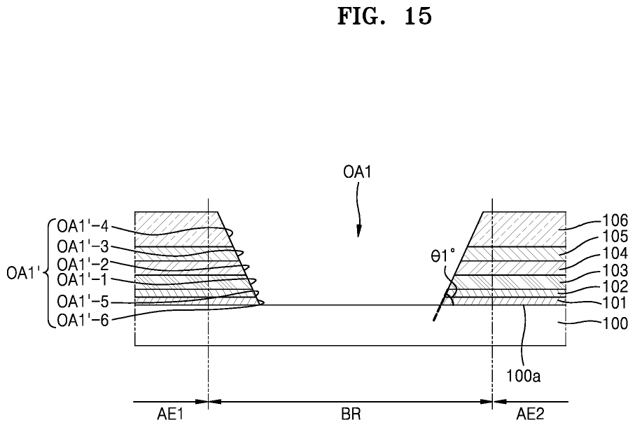

FIG. 15 is a schematic cross-sectional view of a region around the first opening OA1 of the display apparatus of FIG. 1.

Referring to FIG. 15, a first-apostrophe opening OA1′ may extend to the upper surface of the substrate 100 without the third opening OA3. For example, the first-apostrophe opening OAF may expose a portion of the upper surface of the substrate 100 to the outside. Accordingly, the first-apostrophe opening OA1′ may further include a 1′-5^{th} opening OA1′-5 included in the buffer layer 102 and a 1′-6^{th} opening OA1′-6 included in the barrier layer 101 as sub-openings.

Also, a 1′-1^{st} opening to a 1′-4^{th} opening OA1′-1 to OA1′-4 of the first-apostrophe opening OA1′ may be respectively the same as the 1-1^{st} opening to the 1-4^{th} opening OA1-1 to OA1-4 described above with reference to FIGS. 8 and 9, and thus, their descriptions are omitted.

The first-apostrophe opening OA1′ may be simultaneously formed with the second opening OA2 arranged in the transmission area TA, and thus, the second opening OA2 may extend to the upper surface of the substrate 100 to correspond to the first-apostrophe opening OA1′ of FIG. 15. For example, the second opening OA2 may also further include a 2′-5^{th} opening (not shown) and a 2′-6^{th} opening (not shown) corresponding to the 1′-5^{th} opening OAF-5 and the 1′-6^{th} opening OA1′-6, respectively.

In other words, the buffer layer 102 may include the 1′-5^{th} opening OA1′-5 in the bending area BR and the 2′-5^{th} opening in the transmission area TA, and the barrier layer 101 may include the 1′-6^{th} opening OA1′-6 in the bending area BR and the 2′-6^{th} opening in the transmission area TA.

The 1′-5^{th} opening OA1′-5 may expose a portion of the upper surface of the buffer layer 102 through the 1′-6^{th} opening OA1′-6. An inner surface of the 1′-5^{th} opening OAF-5 may be continuously formed with an inner surface of the 1′-1^{st} opening OAF-1 and an inner surface of the 1′-6^{th} opening OA1′-6. When viewed in a direction perpendicular to the substrate 100, an area of the 1′-5^{th} opening OAF-5 may increase in a direction toward the buffer layer 102 from the substrate 100.

The 1′-6^{th} opening OA1′-6 may expose a portion of the upper surface of the substrate 100 to the outside. The inner surface of the 1′-6^{th} opening OA1′-6 may be continuously formed with the inner surface of the 1′-5^{th} opening OAF-5. When viewed in a direction perpendicular to the substrate 100, an area of the 1′-6^{th} opening OA1′-6 may increase in a direction toward the barrier layer 101 from the substrate 100.

Hereinafter, a method of manufacturing a display apparatus (hereinafter, a manufacturing method), according to another embodiment, is described in detail below, based on the above descriptions.

For reference, when describing the method of manufacturing the display apparatus, aspects that are the same as or correspond to the aspects described above may not be described.

Also, the first opening OA1 described in this specification may be a component simultaneously formed with the second opening OA2 arranged in the transmission area TA, and it is assumed that the first opening OA1 may be formed together with the second opening OA2 by a dry etching process for forming the second opening OA2.

For reference, a process for forming the first through-hole TH1 may be a process for forming a through-hole having a high aspect ratio, and the process may use a dry etching process, but may not include a hard bake process. For example, the process for forming the first through-hole TH1 may not perform the hard bake process after a photoresist (PR) process, and thus, may minimize reflow of the photoresist. By minimizing the reflow, an inclination of a side surface included in an end of the photoresist, with respect to the upper surface of the substrate, may be relatively steep.

On the contrary, a process for forming the second opening OA2 may be a process for forming an opening having a low aspect ratio, and the process may use a dry etching process and may include a hard bake process. For example, the process for forming the second opening OA2 may perform the hard bake process after the PR process, and thus, may induce reflow of the photoresist. By inducing the reflow, an inclination of a side surface included in an end of the photoresist, with respect to the upper surface of the substrate, may be relatively low.

Accordingly, a process for forming the first opening OA1 may have to form an opening having a low aspect ratio, and thus, it is desirable to simultaneously form the first opening OA1 with the second opening OA2, rather than the first through-hole TH1.

Based on this aspect, the method of manufacturing the display apparatus according to an embodiment is described below.

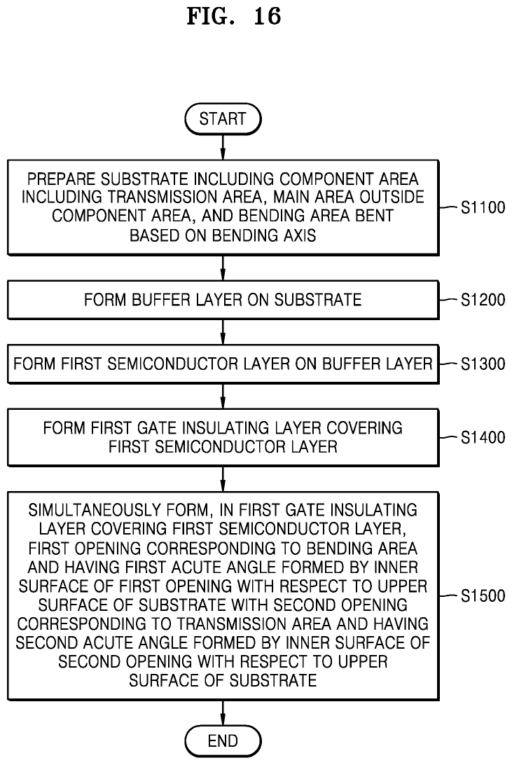

FIG. 16 is a schematic flowchart of a method of manufacturing a display apparatus, according to an embodiment.

As illustrated in FIG. 16, the method of manufacturing the display apparatus may include an operation (S1100) of preparing the substrate 100 including the component area CA including the transmission area TA, the main area AE1 outside the component area CA, and the bending area BR bending based on a bending axis. For example, the substrate 100 may include polymer resins and may have a flexible, rollable, and/or bendable property.

The manufacturing method may include, after preparing the substrate 100, an operation (S1200) of forming the buffer layer 102 on the substrate 100. Here, the buffer layer 102 may include silicon oxide, silicon nitride, silicon oxynitride, and/or the like.

According to cases, the operation (S1200) of forming the buffer layer 102 on the substrate 100 may include forming the barrier layer 101 on the substrate 100 and forming the buffer layer 102 on the barrier layer 101. The barrier layer 101 may include an inorganic material, and the barrier layer 101 may be included in a multi-layered structure together with the substrate 100 including polymer resins.

The manufacturing method may include, after forming the buffer layer 102, an operation (S1300) of forming the first semiconductor layer 110 on the buffer layer 102. The operation (S1300) of forming the first semiconductor layer 110 may also include, after forming the first semiconductor layer 110, a process of patterning the first semiconductor layer 110 to have a predetermined or given shape.

The manufacturing method may include, after forming the first semiconductor layer 110, an operation (S1400) of forming, on the first semiconductor layer 110, the first gate insulating layer 103 covering the first semiconductor layer 110. The first gate insulating layer 103 may have a shape corresponding to the entire surface of the substrate 100 and may be formed by CVD or ALD.

The manufacturing method may include, after forming the first gate insulating layer 103 by using deposition, an operation (S1500) of simultaneously forming the 1-1^{st} opening OA1-1 and the 2-1^{st} opening OA2-1 on the first gate insulating layer 103. Here, the 1-1^{st} opening OA1-1 may correspond to the bending area BR and may have the first acute angle θ1° formed by the inner surface of the 1-1^{st} opening OA1-1 with respect to the upper surface of the substrate 100. Also, the 2-1^{st} opening OA2-1 may correspond to the transmission area TA and may have the second acute angle θ4° formed by the inner surface of the 2-1^{st} opening OA2-1 with respect to the upper surface of the substrate 100. Here, the 1-1^{st} opening OA1-1 and the 2-1^{st} opening OA2-1 may be simultaneously formed with each other, and thus, the first acute angle θ1° and the second acute angle θ4° may be the same.

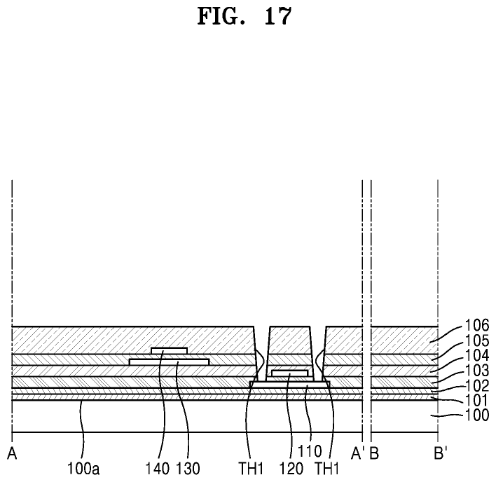

FIGS. 17 to 19 are cross-sectional views for describing, in chronological order, processes of forming the first opening OA1 and the third opening OA3 in a method of manufacturing a display apparatus.

As illustrated in FIG. 17, the manufacturing method may include, after forming the first to fourth gate insulating layers 103 to 106, forming the first through-hole TH1 first. The first through-hole TH1 may include the sub-through-holes penetrating the first to fourth gate insulating layers 103 to 106 and may expose a portion of the upper surface of the first semiconductor layer 110 to the outside.

To form the first through-hole TH1, the manufacturing method may include an etching process using a mask having a pattern of a predetermined or given shape according to a portion of the upper surface of the first semiconductor layer 110, the portion being to be exposed to the outside.

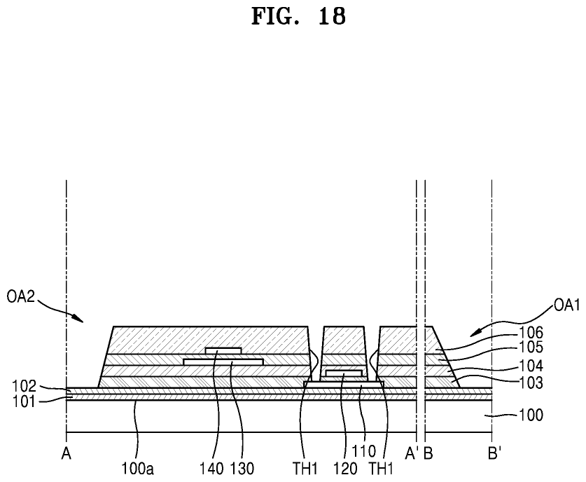

As illustrated in FIG. 18, the manufacturing method may include, after forming the first through-hole TH1, simultaneously forming the first opening OA1 and the second opening OA2. As described above, the first opening OA1 and the second opening OA2 may include the sub-openings penetrating the first to fourth gate insulating layers 103 to 106 and may expose a portion of the upper surface of the buffer layer 102 to the outside.

Because the first opening OA1 and the second opening OA2 may be simultaneously formed, the characteristics of the first opening OA1 and the second opening OA2 may be the same or substantially the same as each other. However, in the case of the bending area BR, to reduce bending stress, the buffer layer 102 and/or the barrier layer 101 may also have to be removed.

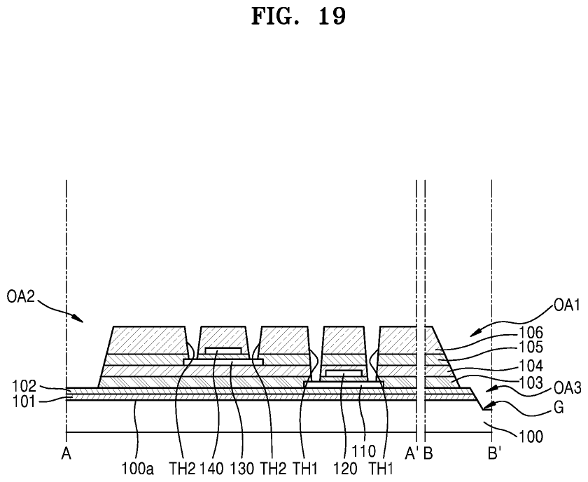

As illustrated in FIG. 19, the manufacturing method may include, after forming the first opening OA1 and the second opening OA2, simultaneously forming the second through-hole TH2 and the third opening OA3. As described above, the second through-hole TH2 may include the sub-through-holes penetrating the third and fourth gate insulating layers 105 and 106, and the third opening OA3 may include the sub-openings penetrating the buffer layer 102 and the barrier layer 101.

For reference, descriptions about the sub-through-holes and the sub-openings may be the same as or correspond to the descriptions above, and thus, may be omitted.

The second through-hole TH2 and the third opening OA3 may be simultaneously formed, and thus, the characteristics of the second through-hole TH2 and the third opening OA3 may be the same or substantially the same as each other. However, in the case of the bending area BR, an acute angle with respect to the upper surface of the substrate 100 may have to be decreased to reduce the bending stress. Also, while the second through-hole TH2 may have a little area, when viewed in a direction perpendicular to the substrate 100, the third opening OA3 may require a relatively greater area for bending, viewed in the direction perpendicular to the substrate 100.

Thus, in the process of simultaneously forming the second through-hole TH2 and the third opening OA3, a slit mask having a predetermined or given pattern corresponding to a location of the third opening OA3 may be used. In case that the slit mask is used, the opening having a greater area and a less taper angle than the through-hole may be formed.

As illustrated in FIG. 19, the manufacturing method may further include, after forming the third opening OA3, forming the groove G. During an etching process, an ashing process for removing residue etching gas may be accompanied, and during the ashing process, the groove G may further be formed in the substrate 100 to correspond to the third opening OA3.

Also, although not illustrated in FIGS. 17 to 19, it may be understood by one of ordinary skill in the art that the display apparatus including the additional gate layer and the additional gate insulating layer may also be formed by using the same process.

According to an embodiment described above, a display apparatus and a method of manufacturing the same may be realized, whereby an opening may be formed in a bending area, simultaneously with an opening formed in a transmission area, and thus, the opening may be formed in the bending area to have an inner surface having a relatively low taper angle. However, the scope of the disclosure is not limited to this effect as described above.

It should be understood that embodiments described herein should be considered in a descriptive sense only and not for purposes of limitation. Descriptions of features or aspects within each embodiment should typically be considered as available for other features or aspects in other embodiments. While one or more embodiments have been described with reference to the figures, it will be understood by those of ordinary skill in the art that various changes in form and details may be made therein without departing from the spirit and scope of this disclosure.

What is claimed is:

1. A display apparatus comprising:
a substrate including:
a component area including a transmission area;
a main area outside the component area; and
a bending area bent based on a bending axis;
a buffer layer disposed on the substrate;
a first semiconductor layer disposed on the buffer layer; and
a first gate insulating layer overlapping the first semiconductor layer and including:
a 1-1^{st} opening corresponding to the bending area; and
a 1-1^{st} through-hole exposing a portion of the first semiconductor layer,
wherein
a first acute angle formed by an inner surface of the 1-1^{st} opening with respect to an upper surface of the substrate is less than a first contact acute angle formed by an inner surface of the 1-1^{st} through-hole with respect to the upper surface of the substrate.

2. The display apparatus of claim 1, further comprising:
a plurality of auxiliary pixels arranged in the component area,
wherein the first gate insulating layer further includes a 2-1^{st} opening corresponding to the transmission area disposed between the plurality of auxiliary pixels.

3. The display apparatus of claim 2, wherein a second acute angle formed by an inner surface of the 2-1^{st} opening with respect to the upper surface of the substrate is the same as the first acute angle.

4. The display apparatus of claim 1, further comprising:
a second gate insulating layer disposed on the first gate insulating layer;
a second semiconductor layer disposed on the second gate insulating layer; and
a third gate insulating layer overlapping the second semiconductor layer.

5. The display apparatus of claim 4, wherein
the second gate insulating layer includes a 1-2^{nd} through-hole corresponding to the 1-1^{st} through-hole, and
an inner surface of the 1-2^{nd} through-hole and the inner surface of the 1-1^{st} through-hole form a continuous surface with each other.

6. The display apparatus of claim 5, wherein the third gate insulating layer includes a 2-1^{st} through-hole exposing a portion of the second semiconductor layer and includes a second contact acute angle formed by an inner surface of the 2-1^{st} through-hole with respect to the upper surface of the substrate.

7. The display apparatus of claim 6, wherein
the buffer layer includes a 3-1^{st} opening corresponding to the bending area, and
a third acute angle formed by an inner surface of the 3-1^{st} opening with respect to the upper surface of the substrate is less than the first acute angle.

8. The display apparatus of claim 7, wherein the third acute angle is less than the second contact acute angle.

9. The display apparatus of claim 7, wherein, when viewed in a direction perpendicular to the substrate, an area of the 1-1^{st} opening is greater than an area of the 3-1^{st} opening.

10. The display apparatus of claim 7, wherein, when viewed in a direction perpendicular to the substrate, the 3-1^{st} opening is disposed in the 1-1^{st} opening.

11. The display apparatus of claim 10, wherein the substrate further includes a groove corresponding to the 3-1^{st} opening.

12. The display apparatus of claim 11, wherein a fourth acute angle formed by an inner surface of the groove with respect to the upper surface of the substrate is the same as or less than the third acute angle.

13. The display apparatus of claim 11, wherein an inner surface of the groove and the inner surface of the 3-1^{st} opening form a continuous surface with each other.

14. The display apparatus of claim 4, further comprising:
an organic interlayer insulating layer disposed on the third gate insulating layer; and
an organic material layer filling the 1-1^{st} opening and including a same material as the organic interlayer insulating layer.

15. A method of manufacturing a display apparatus, the method comprising:
preparing a substrate including a component area including a transmission area, a main area outside the component area, and a bending area bent based on a bending axis;
forming a buffer layer on the substrate;
forming a first semiconductor layer on the buffer layer;
forming a first gate insulating layer overlapping the first semiconductor layer; and
simultaneously forming, in the first gate insulating layer, a 1-1^{st} opening corresponding to the bending area and including a first acute angle formed by an inner surface of the 1-1^{st} opening with respect to an upper surface of the substrate with a 2-1^{st} opening corresponding to the transmission area and including a second acute angle formed by an inner surface of the 2-1^{st} opening with respect to the upper surface of the substrate.

16. The method of claim 15, further comprising:
forming, in the first gate insulating layer, a 1-1^{st} through-hole exposing a portion of the first semiconductor layer and including a first contact acute angle formed by an inner surface of the 1-1^{st} through-hole with respect to the upper surface of the substrate,
wherein the first contact acute angle is greater than the first acute angle.

17. The method of claim 15, further comprising:
forming a second gate insulating layer on the first gate insulating layer;
forming a second semiconductor layer on the second gate insulating layer; and
forming a third gate insulating layer overlapping the second semiconductor layer.

18. The method of claim 17, further comprising:
forming, in the third gate insulating layer, a 2-1^{st} through-hole exposing a portion of the second semiconductor layer and including a second contact acute angle with respect to the upper surface of the substrate.

19. The method of claim 18, wherein the forming of the 2-1^{st} through-hole in the third gate insulating layer comprises forming, in the third gate insulating layer, simultaneously with the 2-1^{st} through-hole, a 3-1^{st} opening corresponding to the bending area and including a third acute angle formed by an inner surface of the 3-1^{st} opening with respect to the upper surface of the substrate.

20. The method of claim 19, wherein, when viewed in a direction perpendicular to the substrate, an area of the 1-1^{st} opening is greater than an area of the 3-1^{st} opening.
